(19) United States
(12) Patent Application Publication
(10) Pub. No.: US 2011/0210407 A1
(43) Pub. Date: Sep. 1, 2011

(54) DOUBLE-FACED ADHESIVE FILM AND ELECTRONIC COMPONENT MODULE USING SAME

(76) Inventors: Youji Katayama, Ibaraki (JP); Yuuki Nakamura, Ibaraki (JP); Masanobu Miyahara, Ibaraki (JP); Koichi Kimura, Ibaraki (JP); Tsutomu Kitakatsu, Ibaraki (JP)

(21) Appl. No.: 13/060,670

(22) PCT Filed: Aug. 25, 2009
(86) PCT No.: PCT/JP2009/064765

§ 371 Date: May 17, 2011

(30) Foreign Application Priority Data
Aug. 27, 2008 (JP) 2008-218049
Oct. 15, 2008 (JP) 2008-266243
Jan. 7, 2009 (JP) 2009-001749
Jan. 26, 2009 (JP) 2009-014296
Jul. 31, 2009 (JP) 2009-179789

(51) Int. Cl. H01L 29/66; B32B 7/12; H01L 23/58

(52) U.S. Cl. 257/414; 428/343; 428/355 EN; 428/355 AK; 257/798; 257/E29.166; 257/E23.002

(57) ABSTRACT

A double-faced adhesive film including: a supporting film; a first adhesive layer laminated on one surface of the supporting film; and a second adhesive layer laminated on the other surface of the supporting film, wherein the glass transition temperatures, after curing, of the first adhesive layer and the second adhesive layer are each 100° C. or lower, and the first adhesive layer and the second adhesive layer are the layers capable of being formed by a method including the steps of directly applying a varnish to the supporting film and drying the applied varnish.

### TECHNICAL FIELD

The present invention relates to a double-faced adhesive film and an electronic component module using the same.

### BACKGROUND ART

Recently, in the field of semiconductor packages, the cases where two or more, same or different semiconductor elements are mounted in one package have been increased as shown in Patent Literature 1 and Patent Literature 2. For example, in such a case, as in SIP (System In Package), where a package has two or more types of semiconductor elements mounted on one flat surface, the distances between the elements are required to be made as shorter as possible for the purpose of mounting in higher densities. When two or more semiconductor elements are laminated to be mutually superposed, it is important to maintain the thickness of the adhesive film to be constant. Additionally, in mounting sensor elements or MEMS elements on a substrate, there are a case where the mounting locations themselves of the elements are important and a case where the distance or the mounting height difference between the functional sites located at different positions in an element is important. Further, there is a case where the distance or the mounting height difference between the adjacent elements is important. For example, when two or more image sensor elements are mounted on one flat surface, it is important to suppress the variation of the distance or the mounting height difference between the adjacent elements. Additionally, in the applications to LED printer heads, it is required to arrange an enormous number of LEDs with equally spaced intervals.

### CITATION LIST

### Patent Literature

Patent Literature 1: Japanese Patent Application Laid-Open Publication No. 2006-307055
Patent Literature 2: Japanese Patent Application Laid-Open Publication No. 2007-277522
Patent Literature 3: Japanese Patent Application Laid-Open Publication No. 2006-282973
Patent Literature 4: Japanese Patent Application Laid-Open Publication No. 2003-060127

### SUMMARY OF INVENTION

### Technical Problem

However, conventional adhesive films which are used to adhere elements to substrates have a problem that such adhesive films are large in the deformation accompanying heating, and further improvement has been demanded with respect to this problem.

For example, when an element is adhered to a substrate by a method in which after an adhesive film is pressure bonded to one adherend (the substrate or the element), the other adherend (the substrate or the element) is pressure bonded, it is necessary to apply a sufficient pressure at a temperature equal to or higher than the glass transition temperature (Tg), after curing, of the adhesive film when the adhesive film is pressure bonded to the one adherend; however, due to the heating at such a high temperature, the adhesive film surface on the side not in contact with the adherend, namely, the side in contact with a jig for pressure bonding is deformed by the heat and the pressure, and thus fine asperities are formed on the surface as the case may be. When the fine asperities are formed on the surface of the adhesive film before the other adherend is pressure bonded, the adhesion of the other adherend with a high precision becomes difficult, and additionally, there is a possibility that such fine asperities become a cause for the decrease of the adhesion strength.

In the steps involving heating such as the steps of curing, wire bonding and sealing of the adhesive film, performed after the pressure bonding of the adherends, the adhesive film sometimes undergoes the deformation such as thermal expansion, thermal shrinkage, cure shrinkage or the expansion accompanying the volatilization of the volatile components and the hygroscopic moisture in the adhesive film. When this deformation is large, there occurs a problem that the position of the mounted element deviates. In particular, when two or more elements are adhered to one and the same surface of the continuous adhesive film formed on the substrate, the distance(s) and the height(s) between the elements vary due to heating.

Further, there has been a problem that warpage occurs when a substrate and elements are adhered to each other with an adhesive film. There is a possibility that this warpage becomes a cause for the variation of the distances and heights between the functional sites of one and the same element or between the elements.

Accordingly, the present invention takes as its object the provision of a double-faced adhesive film in which the deformation and the warpage at the time of being heated are sufficiently suppressed.

### Solution to Problem

Specifically, a first double-faced adhesive film of the present invention is a double-faced adhesive film including: a supporting film; a first adhesive layer laminated on one surface of the supporting film; and a second adhesive layer laminated on the other surface of the supporting film, wherein the glass transition temperatures, after curing, of the first adhesive layer and the second adhesive layer are each 100° C. or lower, and the first adhesive layer and the second adhesive layer are the layers capable of being formed by a method including the steps of directly applying a varnish to the supporting film and drying the applied varnish.

According to the double-faced adhesive film, the deformation and warpage at the time of being heated are sufficiently suppressed. By setting the glass transition temperatures (Tgs), after curing, of the first adhesive layer and the second adhesive layer at 100° C. or lower, it is possible to perform the step of pressure bonding a substrate and an element to each other at a lower temperature. By performing the pressure bonding at a low temperature, the effects of the difference between the coefficient of linear expansion of the substrate and the coefficient of linear expansion of the element becomes small, and consequently it is possible to suppress the warpage.

Additionally, when such a double-faced adhesive film of the present invention as described above, composed of at least three layers is used for the adhesion between an element such as a semiconductor element and the substrate, it is possible to maintain a sufficient adhesion force even after heating at high temperatures and after solvent immersion. Further, the double-faced adhesive film can attain a higher level, by using the supporting film, also with respect to the compatibility between the reduction of the thermal stress and the processability of the adhesive film.

In the double-faced adhesive film, it is preferable that the glass transition temperature, after curing, of the first adhesive layer is higher by 10° C. or more than the glass transition temperature, after curing, of the second adhesive layer. Herewith, it is possible to suppress the deformation of the adhesive film due to the heat at the time of pressure bonding. For example, in the step in which first the second adhesive layer side of the adhesive film is pressure bonded to an element or a substrate, the Tg, after curing, of the first adhesive layer is higher than the Tg, after curing, of the second adhesive layer; in other words, the temperature required for deforming the first adhesive layer and adhering the first adhesive layer is higher than the temperature required for deforming the second adhesive layer and adhering the second adhesive layer, and hence it is possible to pressure bond the second adhesive layer at a temperature at which the deformation of the first adhesive layer hardly occurs. Consequently, it is possible to suppress the deformation of the first adhesive layer.

It is preferable that the flow magnitudes of the first adhesive layer and the second adhesive layer are each 0 to 2000 μm. When the flow magnitude exceeds 2000 μm, the processability of the double-faced adhesive film with respect to the hole drilling, punching and the like lowers. It is to be noted that the flow magnitude is an index for the melt fluidity of the adhesive layer at the time of thermal pressure bonding, and the measurement method of the flow magnitude is as described below.

It is preferable that the first adhesive layer and/or the second adhesive layer includes a thermoplastic resin and a thermosetting resin, and further includes a filler.

It is preferable that the thermoplastic resin includes a polyimide resin and the glass transition temperature of the thermoplastic resin is 100° C. or lower.

It is preferable that the supporting film has a coefficient of linear expansion of 100 ppm or less. By setting the coefficient of linear expansion of the supporting film at 100 ppm or less, in other words, by using as the supporting film a material being small in the property variation at the time of heating, it is possible to suppress the shrinkage and the expansion of the adhesive film itself in heating steps, after mounting the element on the substrate, such as a step of curing the adhesive film, a wire bonding step and a sealing step. Consequently, suppressed is the deviation of the position of the mounted elements on the occasion of these heating steps. The coefficient of linear expansion of silicon (Si), which is a material to constitute semiconductor elements and MEMS elements, is a few ppm, and the coefficients of linear expansion of general substrates such as glass epoxy substrates and BT substrates are a few tens ppm. On the other hand, the coefficients of linear expansion of conventional adhesive films are generally a few hundred ppm, and it is difficult to reduce the warpage occurring due to the differences between the coefficient of linear expansion of the substrate and the coefficients of linear expansion of the elements, and also the differences between the coefficients of linear expansion of the substrate and elements and the coefficient of linear expansion of the adhesive film. When warpage occurs, there is a possibility that the distances between the elements and the mounting heights of the elements vary. By setting the coefficient of linear expansion of the supporting film at 100 ppm or less, it is possible to effectively reduce the warpage.

It is preferable that the supporting film has a glass transition temperature of 100° C. or higher. Herewith, it is possible to suppress the possibility that the supporting film deforms at the pressure bonding temperature of the adhesive film.

It is preferable that the double-faced adhesive film includes cover films laminated respectively on the surfaces, opposite to the supporting film, of the first adhesive layer and the second adhesive layer. It is possible to use such a double-faced adhesive film for adhering semiconductor elements and/or MEMS elements to a substrate.

The double-faced adhesive film is particularly useful when used for the purpose of adhering semiconductor elements and/or MEMS elements to the substrate by a method including a step of hole drilling processing of the double-faced adhesive film and a step of removing the cover films from the double-faced adhesive film having been subjected to hole drilling processing. In this case, it is preferable to remove, from the double-faced adhesive film having been subjected to the hole drilling processing, the cover films together with foreign matter produced by the hole drilling processing.

By using the double-faced adhesive film of the present invention when elements are adhered by such a method as described above including a step of hole drilling processing, sufficiently suppressed are troubles such as the adhesive strength decrease and the reliability degradation ascribable to foreign matter such as burrs occurring in accompanying the hole drilling processing. For example, it is possible to prevent the troubles ascribable to the foreign matter by removing the foreign matter occurring in accompanying the hole drilling processing by peeling off the cover film before pressure bonding to one adherend, and further by removing the foreign matter by peeling the other cover film before heat-pressure bonding of the other adherend.

A second double-faced adhesive film of the present invention is a double-faced adhesive film including: a supporting film; a first adhesive layer laminated on one surface of the supporting film; and a second adhesive layer laminated on the other surface of the supporting film, wherein the glass transition temperatures, after curing, of the first adhesive layer and the second adhesive layer are each 100° C. or lower, and the glass transition temperature, after curing, of the first adhesive layer is higher by 10° C. or more than the glass transition temperature, after curing, of the second adhesive layer; and the supporting film has a coefficient of linear expansion of 100 ppm or less.

According to the double-faced adhesive film, the deformation and warpage at the time of being heated are sufficiently suppressed. By setting the Tg, after curing, of the first adhesive layer to be higher by 10° C. or more than the Tg, after curing, of the second adhesive layer, it is possible to suppress the deformation of the adhesive film due to the heat at the time of pressure bonding. For example, in the step in which first the second adhesive layer side of the adhesive film is pressure bonded to an element or a substrate, the Tg, after curing, of the first adhesive layer is higher than the Tg, after curing, of the second adhesive layer; in other words, the temperature required for deforming and adhering the first adhesive layer is higher than the temperature required for deforming and adhering the second adhesive layer, and hence it is possible to pressure bond the second adhesive layer at a temperature at which the deformation of the first adhesive layer hardly occurs. Consequently, it is possible to suppress the deformation of the first adhesive layer.

Additionally, by setting the coefficient of linear expansion of the supporting film at 100 ppm or less, in other words, by using as the supporting film a material being small in the property variation at the time of heating, it is possible to suppress the shrinkage and the expansion of the adhesive film itself in heating steps, after mounting the element on the substrate, such as a step of curing the adhesive film, a wire bonding step and a sealing step. Consequently, suppressed is the deviation of the position of the mounted element on the occasion of these heating steps.

By setting the Tgs, after curing, of the first adhesive layer and the second adhesive layer at 100° C. or lower, it is possible to perform the step of pressure bonding a substrate and an element to each other at a lower temperature. By performing the pressure bonding at a low temperature, the effects of the difference between the coefficient of linear expansion of the substrate and the coefficient of linear expansion of the element becomes small, and consequently it is possible to suppress the warpage.

It is preferable that the first adhesive layer and/or the second adhesive layer includes a thermoplastic resin, a thermosetting resin and a filler.

A third double-faced adhesive film of the present invention is a double-faced adhesive film including: a supporting film; and adhesive layers laminated respectively on both surfaces of the supporting film, wherein the adhesive layers are the layers capable of being formed by a method including the steps of directly applying a varnish to the supporting film and drying the applied varnish, and the flow magnitudes of the adhesive layers are each 0 to 2000 μm and the adhesive layers after curing each have a glass transition temperature of 100° C. or lower.

When such a double-faced adhesive film as described above, composed of at least three layers is used for the adhesion between an element such as a semiconductor element and the substrate, such a double-faced adhesive film can maintain a sufficient adhesion force even after heating at high temperatures and after solvent immersion.

It is preferable that the supporting film has a glass transition temperature of 100° C. or higher and a coefficient of linear expansion of 100 ppm or less.

It is preferable that the adhesive layers each include a polyimide resin and a thermosetting resin.

A fourth double-faced adhesive film of the present invention is a double-faced adhesive film including: a supporting film; adhesive layers laminated respectively on both surfaces of the supporting film, and cover films laminated respectively on the surfaces, opposite to the supporting film, of the adhesive layers. The fourth double-faced adhesive film is used for the purpose of adhering a semiconductor element and/or a MEMS element to a substrate.

The double-faced adhesive film is particularly useful when the double-faced adhesive film is used for the purpose of adhering a semiconductor element and/or a MEMS element to a substrate by a method including a step of hole drilling processing of the double-faced adhesive film and a step of removing the cover films from the double-faced adhesive film having been subjected to hole drilling processing. In this case, it is preferable that from the double-faced adhesive film having been subjected to the hole drilling processing, the cover films are removed together with the foreign matter produced by the hole drilling processing.

When an element is adhered by such a method as described above including a step of hole drilling processing, by using the fourth double-faced adhesive film, sufficiently suppressed are troubles such as the adhesive strength decrease and the reliability degradation ascribable to foreign matter such as burrs occurring in accompanying the hole drilling processing. For example, it is possible to prevent the troubles ascribable to the foreign matter by removing the foreign matter occurring in accompanying the hole drilling processing by peeling off the cover film before pressure bonding to one adherend, and further by removing the foreign matter by peeling the other cover film before heat-pressure bonding of the other adherend.

From the above-described reasons, it is preferable that in the double-faced adhesive film, the supporting film has a coefficient of linear expansion of 100 ppm or less and the adhesive layers after curing each have a glass transition temperature of lower than 100° C.

It is preferable that the supporting film is a film of a polymer selected from the group consisting of aromatic polyimide, aromatic polyamideimide, aromatic polyethersulfone, polyphenylene sulfide, aromatic polyetherketone, polyarylate, polyethylene naphthalate and liquid crystal polymers.

It is preferable that the respective adhesive layers have the same compositions as each other. It is also preferable that the respective adhesive layers each include a thermoplastic resin having a glass transition temperature of 100° C. or lower, a thermosetting resin and a filler.

It is preferable that the supporting film in each of the first to third double-faced adhesive films of the present invention is a film of a polymer selected from the group consisting of polyethylene terephthalate, polybutylene terephthalate, polyethylene naphthalate, polyimide, polyamide, polyamideimide, polyacetal, polycarbonate, polyethersulfone, polyphenylene sulfide, polyphenylene ether, polyetherketone, polyarylate, polyetheramide, polyetherimide, polyetheramideimide, wholly aromatic polyester and liquid crystal polymers; it is more preferable that the concerned supporting film is a film of a polymer selected from the group consisting of polyethylene terephthalate, polybutylene terephthalate, polyethylene naphthalate, polyimide, polyamide, polyamideimide, polyacetal, polycarbonate, polyethersulfone, polyphenylene sulfide, polyphenylene ether, polyetherketone, polyarylate and liquid crystal polymers; and it is furthermore preferable that the concerned supporting film is a film of a polymer selected from the group consisting of aromatic polyimide, aromatic polyamideimide, aromatic polyethersulfone, polyphenylene sulfide, aromatic polyetherketone, polyarylate, polyethylene naphthalate and liquid crystal polymers.

Further, the present invention relates to an electronic component module including: a substrate; a plurality of elements mounted on the substrate, the plurality of elements being selected from semiconductor elements and MEMS elements; and an adhesive layer intervening between the substrate and the elements, wherein the adhesive layer is formed of the double-faced adhesive film (when the double-faced adhesive film is provided with cover films, the first double-faced adhesive film from which the cover films have been removed) of the present invention.

The electronic component module of the present invention can attain high performances and high reliability on the basis of the fact that elements are mounted on a substrate by using the double-faced adhesive film of the present invention.

### Advantageous Effects of Invention

According to the double-faced adhesive film of the present invention, the deformation and the warpage at the time of being heated are sufficiently suppressed. Further, the double-faced adhesive film of the present invention has sufficient adhesive strength as an adhesive for use in electronic component modules such as semiconductor packages and MEMS modules.

By using the double-faced adhesive film of the present invention in semiconductor packages and MEMS modules, it is possible to mount semiconductor elements and MEMS elements with high positional accuracy, high density and sufficient adhesive strength. Therefore, it is possible to obtain high-performance, high-reliability semiconductor packages and MEMS modules.

When the double-faced adhesive film according to the present invention is used as an adhesive film for adhering a plurality of elements to a substrate, it is possible to suppress the effects of the foreign matter occurring in accompanying the processing such as hole drilling, and the deformation due to heating is also suppressed.

### BRIEF DESCRIPTION OF DRAWINGS

FIG. 1 is a cross sectional view illustrating an embodiment of the double-faced adhesive film of the present invention.

FIG. 2 is a cross sectional view illustrating an embodiment of the electronic component module of the present invention.

FIG. 3 is a schematic view illustrating an embodiment of exposure with an LED printer head.

FIG. 4 is a schematic view illustrating an embodiment of exposure with an LED printer head.

FIG. 5 is a schematic view illustrating an embodiment of exposure with an LED printer head.

FIG. 6 is a plan view illustrating a measurement method of the flow magnitude of an adhesive layer.

FIG. 7 is a plan view illustrating a measurement method of the flow magnitude of an adhesive layer.

FIG. 8 is a schematic view illustrating a measurement method of peel strength.

FIG. 9 is a cross sectional view schematically illustrating the condition of the cohesive failure of an adhesive layer.

FIG. 10 is a cross sectional view schematically illustrating the condition of the interface failure of an adhesive layer/supporting film interface.

### DESCRIPTION OF EMBODIMENTS

Hereinafter, with reference to the drawings where necessary, detailed description is made on the embodiments for carrying out the present invention. However, the present invention is not limited to the following embodiments. In the drawings, the same elements are assigned the same reference signs, and the redundant explanations are omitted. The dimensional proportions in the drawings are not limited to the proportions shown in the drawings. “(Meth)acrylic acid” as referred to in the present DESCRIPTION means “acrylic acid” and “methacrylic acid” corresponding thereto.

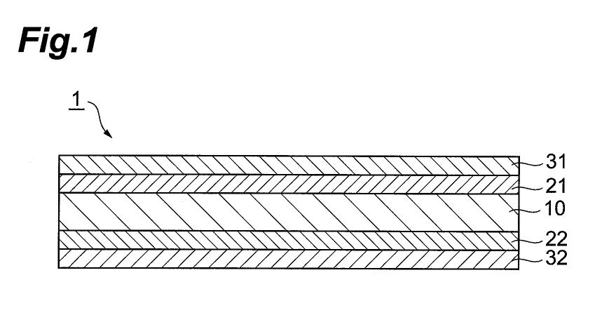

FIG. 1 is a cross sectional view illustrating an embodiment of the double-faced adhesive film of the present invention. The double-faced adhesive film 1 shown in FIG. 1 is a five-layer-structured laminate including: a supporting film 10; a first adhesive layer 21 formed on one surface of the supporting film 10; a second adhesive layer 22 formed on the surface of the supporting film 10, opposite to the first adhesive layer 21; and cover films 31 and 32 laminated respectively on the surfaces, opposite to the supporting film 10, of the first adhesive layer 21 and the second adhesive layer 22. The double-faced adhesive film of the present invention may also be a double-faced adhesive film not including the cover film 31, or may also be a double-faced adhesive film not including the cover film 32.

The first adhesive layer 21 and the second adhesive layer 22 become cured by heating. It is preferable that the glass transition temperatures (Tgs), after curing, of these adhesive layers are each 100° C. or lower. On the basis of the condition that the Tgs, after curing, of these adhesive layers are each 100° C. or lower, the warpage occurring due to the difference between the coefficient of linear expansion of a substrate and the coefficient of linear expansion of an element is reduced. When the Tgs, after curing, of the adhesive layers 21 and 22 are low, it is possible to lower the temperature at the time of thermal pressure bonding. Consequently, the condition that heat is excessively applied to the adhesive film is avoided, and it is also possible to more remarkably suppress the deformation of the adhesive film.

It is preferable that the glass transition temperature, after curing, of the first adhesive layer 21 is higher by 10° C. or more than the glass transition temperature, after curing, of the second adhesive layer 22. Herewith, the effect that the deformation at the time of mounting the element on the substrate is suppressed is remarkably achieved.

The flow magnitudes of the adhesive layers 21 and 22 are preferably 0 to 2000 μm. The flow magnitude is an index for the melt fluidity of the adhesive layer at the time of thermal pressure bonding. When the flow magnitude exceeds 2000 μm, the processability of the double-faced adhesive film with respect to the hole drilling, punching and the like lowers.

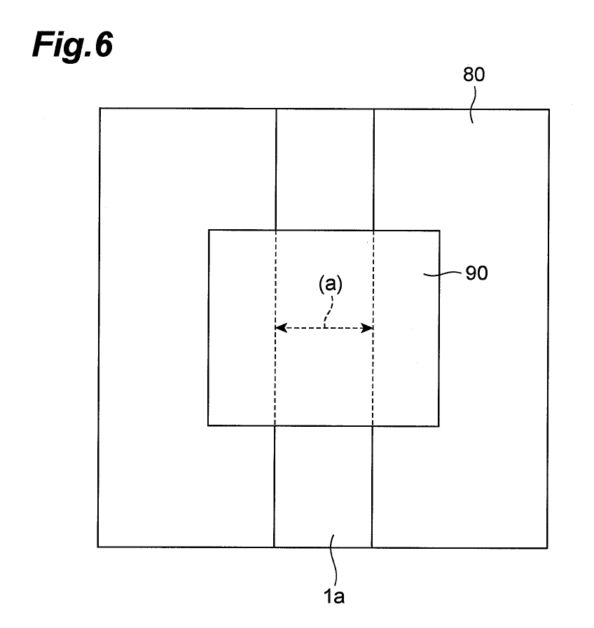

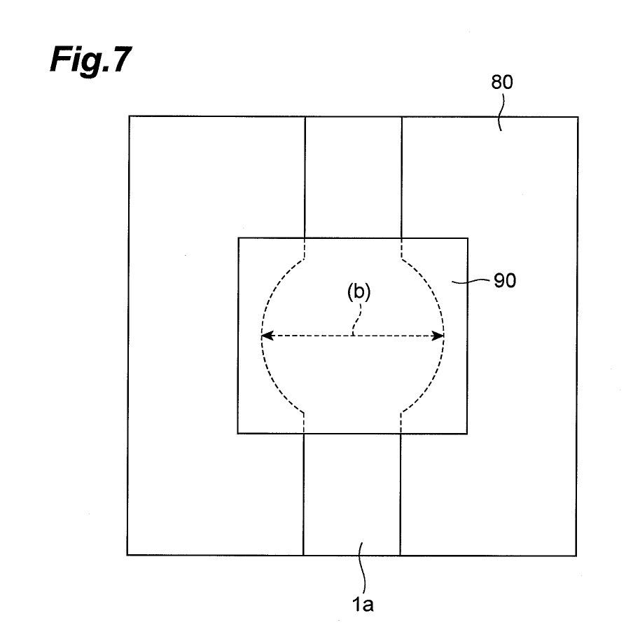

FIGS. 6 and 7 are plan views illustrating measurement methods of the flow magnitude of the adhesive layer. The flow magnitude of the adhesive layer is measured by the following method.

(1) A specimen having a size of 2 mm×10 mm is cut out from a double-faced adhesive film.

(2) The specimen is sandwiched between the 42-alloy lead frame 80 and the 4 mm×4 mm glass chip 90 shown in FIG. 6.

(3) The glass chip 90 is pressure bonded with 50N for 90 seconds while heating at 140° C.

(4) The maximum widths of the double-faced adhesive film (the adhesion layer 1a) before and after the pressure bonding are measured, and the difference between the maximum widths is taken as the flow magnitude. Specifically, when the maximum width of the adhesion layer 1a before the pressure bonding is represented by (a) and the maximum width of the adhesion layer 1a after the pressure bonding is represented by (b), the flow magnitude is obtained from the following formula (see FIGS. 6 and 7).

Flow magnitude(μm)=(b)−(a) Formula

Such Tg and flow magnitude as described above are easily attained by the condition that the first adhesive layer 21 and the second adhesive layer 22 are constituted, for example, by appropriately combining the components described below in detail.

The adhesive layers 21 and 22 each include, for example, a thermoplastic resin and a thermosetting resin.

The Tg of the thermoplastic resin constituting the adhesive layer is preferably 100° C. or lower, more preferably lower than 90° C. and furthermore preferably lower than 80° C. By using a thermoplastic resin in which the Tg is low, it is possible to easily form an adhesive layer having a low Tg. The thermoplastic resin may also be at least one selected from the group consisting of acrylic resin, polyimide resin, polyamideimide resin, polyethersulfone resin, polyacrylate resin, polyetherketone resin, polyarylate, polyetherketone and polyethylene naphthalate. It is preferable that the thermoplastic resin includes polyimide resin among these.

For the purpose of further enhancing the adhesiveness and the heat resistance as the adhesive film, the weight average molecular weight of the polyimide resin measured with GPC (Gel Permeation Chromatography) is preferably 10000 to 500000, more preferably 20000 to 300000, furthermore preferably 30000 to 200000 and particularly preferably 50000 to 100000. When the molecular weight is less than 10000, the strength of the double-faced adhesive film tends to decrease. On the other hand, when the molecular weight exceeds 500000, there is a tendency to cause problems such that the reaction time becomes long in a common solution polymerization method, the redissolution of polyimide resin becomes difficult and the viscosity of the polyimide solution becomes high and the handling thereof becomes difficult. These average molecular weights are, for example, weight average molecular weights measured with gel permeation chromatography, relative to polystyrene standards.

The chemical structure of the polyimide resin constituting the adhesive layer is not particularly limited; however, for the purpose of setting the Tg, after curing, of the adhesive layer at 100° C. or lower, it is preferable that the polyimide resin includes a main chain backbone selected from alkylene, alkylene oxide and siloxane.

It is preferable that the adhesive layers 21 and 22 include the polyimide resin represented by the following formula (I):

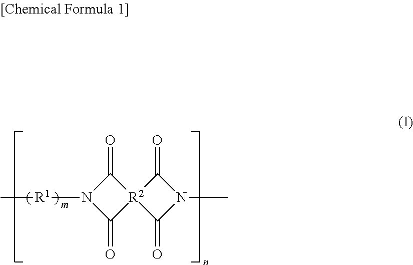

In formula (I), R¹s each independently represent a divalent organic group, m is an integer of 8 to 40, the number of —CH₂—, —CHR— or —CR₂— (R represents an acyclic alkyl group having 1 to 5 carbon atoms) of the m R¹s is k, k/m≧0.85, R² represents a residue of a tetracarboxylic acid dianhydride, and n represents an integer of 1 or more.

It is preferable that k/m≧0.90, and it is more preferable that k/m≧0.95. When k/m<0.85, the hygroscopicity tends to increase and the heat resistance tends to decrease.

R¹ represents the smallest segment of the divalent organic group. For example, R¹ is —CH₂—, —CHR—, —CR₂—, —NH—, —CO—, —Ar—, —S— or —SO—. It is preferable that at least part of the R¹s in the polyimide resin are such that R¹ is —CH₂—, —CHR— or —CR₂— (hereinafter, referred to as methylene groups). Herewith, it becomes possible to set the heating temperature at the time of adhering using the double-faced adhesive film at a low temperature (for example, 120 to 160° C.). The hygroscopicity of the double-faced adhesive film is also further improved. It is preferable that R¹ does not contain any polar group or any polar atom (such as an oxygen atom or a nitrogen atom). When a polar group or a polar atom is contained in R¹, the hygroscopicity tends to increase and the heat resistance tends to decrease.

More specifically, the polyimide resin includes, for example, the structure represented by the following formula (Ia). In formula (Ia), m is an integer of 8 to 20, R¹ represents a residue of an aromatic tetracarboxylic acid and n is an integer of 1 or more.

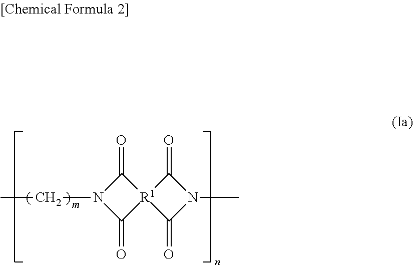

It is possible to obtain the polyimide resin represented by formula (I) by allowing a diamine containing the compound represented by the following formula (II) and a tetracarboxylic acid dianhydride to react with each other. In formula (II), R¹s each independently represent a divalent organic group, m is an integer of 8 to 40, the number of —CH₂—, —CHR— or —CR₂— (R represents an acyclic alkyl group having 1 to 5 carbon atoms) of the m R¹s is k, and k/m≧0.85.

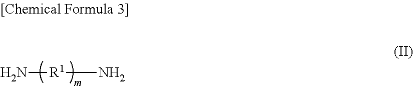

The amount of the diamine represented by formula (II) is preferably 50 mol % or more, more preferably 60 mol % or more and furthermore preferably 70 mo % or more of the whole diamines allowed to react with the tetracarboxylic acid dianhydride.

It is preferable that in the diamine represented by formula (II), the relation k/m≧0.85 holds between the total number m R¹s and the number k of the alkylene groups (—CH₂—, —CHR— or —CR₂—) of R¹s. When k/m<0.85, the hygroscopicity tends to increase and the heat resistance tends to decrease. It is preferable that k/m≧0.90 and it is more preferable that k/m≧0.95. It is preferable that R¹ does not contain any polar group or any polar atom. When a polar group or a polar atom is contained in R¹, the hygroscopicity tends to increase and the heat resistance tends to decrease.

For the purpose of coping with the adhesion at temperatures (120 to 160° C.) lower than conventional adhesion temperatures, m≧8 is preferable and m≧10 is more preferable. Because of the fact that the diamine to be a raw material is easily available, it is preferable that m≦40. However, because there is a tendency to be more effective for the low temperature adhesiveness as m becomes a larger value, it is anticipated that even when m is a numerical value of 40 or more, it is similarly possible to obtain the effect of the low temperature adhesiveness. When the value of m is less than 8, the molecular chain length becomes smaller as compared to the number of moles of the diamine to be used, and hence the effect of the low temperature adhesiveness tends to be small.

Examples of the diamine of formula (II) include: aliphatic diamines such as 1,8-octanediamine (m=k=8), 1,9-nonanediamine (m=k=9), 1,10-decanediamine (m=k=10), 1,11-undecanediamine (m=k=11), 1,12-dodecanediamine (m=k=12), tridecamethylenediamine (m=k=13) and octadecamethylenediamine (m=k=18); and alkyl ethers such as di(5,5′-diaminopentyl)ether (m=11, k=10, k/m=0.91) and 3,3′-(decamethylenedioxy)-bis-(propylamine) (m=18, k=16, k/m=0.89). Preferable among these are the n-alkyldiamines.

For example, the double-faced adhesive film which uses 1,2-dodecanediamine (m=k=12, k/m=1.0) is definitely excellent in reliability, in particular, anti-reflow property even when the composition of the others is the same, as compared to the double-faced adhesive film which uses 1,4-butanediol-bis-(3-aminopropyl)ether (R¹ is of two types, —CH₂— and —O—, m=12, k=10, k/m=0.83), similar in structure to 1,2-dodecanediamine.

The polyimide resin may be a resin obtained by allowing a diamine containing the diamine represented by the following formula (IIa) in an amount of 50 mol % and a tetracarboxylic acid dianhydride to react with each other. In formula (IIa), m is an integer of 8 to 20.

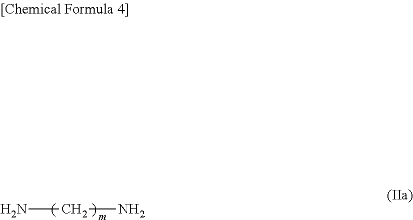

Examples of the other amines which can be used with the diamine represented by formula (II) include: aliphatic diamines such as 1,2-diaminoethane, 1,3-diaminopropane, 1,4-diaminobutane and 1,5-diaminopentane; aromatic diamines such as o-phenylenediamine, m-phenylenediamine, p-phenylenediamine, 3,3′-diaminodiphenyl ether, 3,4′-diaminodiphenyl ether, 4,4′-diaminodiphenyl ether, 3,3′-diaminodiphenylmethane, 3,4′-diaminodiphenylmethane, 4,4′-diaminodiphenylmethane, 3,3′-diaminodiphenyldifluoromethane, 3,4′-diaminodiphenyldifluoromethane, 4,4′-diaminodiphenyldifluoromethane, 3,3′-diaminodiphenylsulfone, 3,4′-diaminodiphenylsulfone, 4,4′-diaminodiphenylsulfone, 3,3′-diaminodiphenylsulfide, 3,4′-diaminodiphenylsulfide, 4,4′-diaminodiphenylsulfide, 3,3′-diaminodiphenylketone, 3,4′-diaminodiphenylketone, 4,4′-diaminodiphenylketone, 2,2-bis(3-aminophenyl)propane, 2,2′-(3,4′-diaminodiphenyl)propane, 2,2-bis(4-aminophenyl)propane, 2,2-bis(3-aminophenyl)hexafluoropropane, 2,2-(3,4′-diaminodiphenyl)hexafluoropropane, 2,2-bis(4-aminophenyl)hexafluoropropane, 1,3-bis(3-aminophenoxy)benzene, 1,4-bis(3-aminophenoxy)benzene, 1,4-bis(4-aminophenoxy)benzene, 3,3′-(1,4-phenylenebis(1-methylethylidene))bisaniline, 3,4′-(1,4-phenylenebis(1-methylethylidene))bisaniline, 4,4′-(1,4-phenylenebis(1-methylethylidene))bisaniline, 2,2-bis(4-(3-aminophenoxy)phenyl)propane, 2,2-bis(4-(4-aminophenoxy)phenyl)propane, 2,2-bis(4-(3-aminophenoxy)phenyl)hexafluoropropane, 2,2-bis(4-(4-aminophenoxy)phenyl)hexafluoropropane, bis(4-(3-aminophenoxy)phenyl)sulfide, bis(4-(4-aminophenoxy)phenyl)sulfide, bis(4-(3-aminophenoxy)phenyl)sulfone and bis(4-(4-aminophenoxy)phenyl)sulfone; 1,1,3,3-tetramethyl-1,3-bis(4-aminophenyl)disiloxane, 1,1,3,3-tetraphenoxy-1,3-bis(4-aminoethyl)disiloxane, 1,1,3,3-tetraphenyl-1,3-bis(2-aminoethyl)disiloxane, 1,1,3,3-tetraphenyl-1,3-bis(3-aminopropyl)disiloxane, 1,1,3,3-tetramethyl-1,3-bis(2-aminoethyl)disiloxane, 1,1,3,3-tetramethyl-1,3-bis(3-aminopropyl)disiloxane, 1,1,3,3-tetramethyl-1,3-bis(3-aminobutyl)disiloxane, 1,3-dimethyl-1,3-dimethoxy-1,3-bis(4-aminobutyl)disiloxane, 1,1,3,3,5,5-hexamethyl-1,5-bis(4-aminophenyl)trisiloxane, 1,1,5,5-tetraphenyl-3,3-dimethyl-1,5-bis(4-aminopropyl)trisiloxane, 1,1,5,5-tetraphenyl-3,3-dimethoxy-1,5-bis(4-aminobutyl)trisiloxane, 1,1,5,5-tetraphenyl-3,3-dimethoxy-1,5-bis(5-aminopentyl)trisiloxane, 1,1,5,5-tetramethyl-3,3-dimethoxy-1,5-bis(2-aminoethyl)trisiloxane, 1,1,5,5-tetramethyl-3,3-dimethoxy-1,5-bis(4-aminobutyl)trisiloxane, 1,1,5,5-tetramethyl-3,3-dimethoxy-1,5-bis(5-aminopentyl)trisiloxane, 1,1,3,3,5,5-hexamethyl-1,5-bis(3-aminopropyl)trisiloxane, 1,1,3,3,5,5-hexaethyl-1,5-bis(3-aminopropyl)trisiloxane and 1,1,3,3,5,5-hexapropyl-1,5-bis(3-aminopropyl)trisiloxane. These can be used each alone or in combinations of two or more thereof.

Particularly preferable among these is the siloxane diamine represented by the following formula (III), particularly from the viewpoint of the balance between the improvement of the workability based on the improvement of the solubility of the polyimide resin in the solvent, the improvement of the adhesion force based on the affinity of the polyimide resin to the substrate, the resistance to the moisture absorption of the polyimide resin, the securement of the reliability based on the chemical stability of the polyimide resin and other factors. It is also possible to use the siloxane diamine represented by formula (III) in combination with other diamines as well as the diamine represented by formula (II).

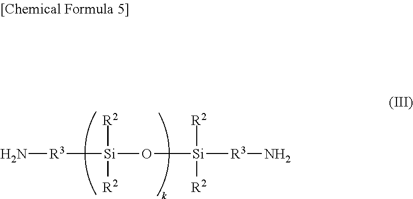

In formula (III), R²s each independently represent a methyl group or a phenyl group, R³s each independently represent a divalent hydrocarbon group having 1 to 6 carbon atoms, and k is an integer of 1 to 8.

In the case where a siloxane diamine in which the chain length is extremely long is used, when the adhesive film is placed under high temperatures, the adhesiveness decrease, considered to be ascribable to the migration of siloxane to the film surface, tends to rapidly proceed. Consequently, the work tolerance of the adhesive film decreases as the case may be. As a specific example, there increases a possibility that when a temporary halt occurs in an automation line of thermal pressure bonding or the like, the adhesive film stopping in the vicinity of a heating jig undergoes failure. From this viewpoint, it is preferable that the chain length of siloxane diamine is short. Specifically, k≦8 is preferable, k≦5 is more preferable and k≦3 is furthermore preferable.

It is possible to evaluate the work tolerance, for example, by a method which measures the adhesive strength at the time of thermal pressure bonding of chips and the like under predetermined conditions after the adhesive film thermally pressure bonded to a substrate or the like is allowed to stand on a high temperature heated plate for a predetermined time of period, and compares the resulting adhesive strength with the adhesive strength at the time of adhesion without allowing stand on a heated plate.

The amount of siloxane diamine is preferably 3 to 50 mol %, more preferably 5 to 45 mol % and furthermore preferably 10 to 40 mol % in relation to the whole of the diamines. When the amount of siloxane diamine is appropriate, the strongest adhesion force is obtained.

The diamine represented by formula (II) includes some diamines which decrease the solubility of the polyimide resin in the solvent, and hence it is preferable to increase the solubility of the resin by combining complementarily another appropriate diamine according to the diamine to be used, for example, by using an diamine excellent in solubility. Herewith, it is possible to facilitate the production of the adhesive film.

The tetracarboxylic acid dianhydride of the raw material for the polyimide resin is not particularly limited; however, from the viewpoint that the moisture resistance of the obtained adhesive film can be increased, it is preferable to increase the used amount of the tetracarboxylic acid dianhydride containing no functional group having hydrolyzability.

The used amount of the tetracarboxylic acid dianhydride containing no functional group having hydrolyzability is preferably 60 mol % or more, more preferably 70 mol % or more and particularly preferably 80 mol % or more of the whole of the tetracarboxylic acid dianhydrides. When this amount is less than 60 mol %, the decomposition in the environment at the glass transition temperature or higher and at a high humidity tends to be accelerated, and the tolerance to the reliability test such as the HAST test (Highly Accelerated temperature and humidity Stress Test) tends to decrease, depending on the structure of the semiconductor device.

Examples of the functional group having hydrolyzability include ester groups of carboxylic acid esters and the like, and amide groups (—NHCO—, with the proviso that the amic acid being an intermediate of the imidization reaction is excluded).

Examples of the tetracarboxylic acid dianhydride containing no functional group having hydrolyzability include: pyromellitic acid dianhydride, 3,3′,4,4′-diphenyltetracarboxylic acid dianhydride, 2,2′,3,3′-diphenyltetracarboxylic acid dianhydride, 2,2-bis(3,4-dicarboxyphenyl)propane dianhydride, 2,2-bis(2,3-dicarboxyphenyl)propane dianhydride, 1,1-bis(2,3-dicarboxyphenyl)ethane dianhydride, 1,1-bis(3,4-dicarboxyphenyl)ethane dianhydride, bis(2,3-dicarboxyphenyl)methane dianhydride, bis(3,4-dicarboxyphenyl)methane dianhydride, bis(3,4-dicarboxyphenyl)sulfone dianhydride, 3,4,9,10-perylenetetracarboxylic acid dianhydride, bis(3,4-dicarboxyphenyl)ether dianhydride, benzene-1,2,3,4-tetracarboxylic acid dianhydride, 3,4,3′,4′-benzophenone tetracarboxylic acid dianhydride, 2,3,2′,3′-benzophenone tetracarboxylic acid dianhydride, 2,3,3′,4′-benzophenone tetracarboxylic acid dianhydride, 1,2,5,6-naphthalene tetracarboxylic acid dianhydride, 2,3,6,7-naphthalene tetracarboxylic acid dianhydride, 1,2,4,5-naphthalene tetracarboxylic acid dianhydride, 1,4,5,8-naphthalene tetracarboxylic acid dianhydride, 2,6-dichloronaphthalene-1,4,5,8-tetracarboxylic acid dianhydride, 2,7-dichloronaphthalene-1,4,5,8-tetracarboxylic acid dianhydride, 2,3,6,7-tetrachloronaphthalene-1,4,5,8-tetracarboxylic acid dianhydride, phenanthrene-1,8,9,10-tetracarboxylic acid dianhydride, pyrazine-2,3,5,6-tetracarboxylic acid dianhydride, thiophene-2,3,4,5-tetracarboxylic acid dianhydride, 2,3,3′,4′-biphenyltetracarboxylic acid dianhydride, 3,4,3′,4′-biphenyltetracarboxylic acid dianhydride, 2,3,2′,3′-biphenyltetracarboxylic acid dianhydride, bis(3,4-dicarboxyphenyl)dimethylsilane dianhydride, bis(3,4-dicarboxyphenyl)methylphenylsilane dianhydride, bis(3,4-dicarboxyphenyl)diphenylsilane dianhydride, 1,4-bis(3,4-dicarboxyphenyldimethylsilyl)benzene dianhydride, 1,3-bis(3,4-dicarboxyphenyl)-1,1,3,3-tetramethyldicyclohexane dianhydride, p-phenylenebis(trimellitate anhydride), ethylenetetracarboxylic acid dianhydride, 1,2,3,4-butanetetracarboxylic acid dianhydride, decahydronaphthalene-1,4,5,8-tetracarboxylic acid dianhydride, 4,8-dimethyl-1,2,3,5,6,7-hexahydronaphthalene-1,2,5,6-tetracarboxylic acid dianhydride, cyclopentane-1,2,3,4-tetracarboxylic acid dianhydride, pyrrolidine-2,3,4,5-tetracarboxylic acid dianhydride, 1,2,3,4-cyclobutanetetracarboxylic acid dianhydride, bicycle[2.2.2]-oct(7)-ene-2,3,5,6-tetracarboxylic acid dianhydride, 2,2-bis(3,4-dicarboxyphenyl)hexafluoropropane dianhydride, 2,2-bis(4-(3,4-dicarboxyphenoxy)phenyl)hexafluoropropane dianhydride, 4,4′-bis(3,4-dicarboxyphenoxy)diphenylsulfide dianhydride, 4,4′-(4,4′-isopropylidenediphenoxy)-bis(phthalic acid anhydride), tetrahydrofuran-2,3,4,5-tetracarboxylic acid dianhydride and bis(exobicyclo[2.2.1]heptane-2,3-dicarboxylic acid dianhydride)sulfone.

It is preferable to use, as such tetracarboxylic acid dianhydride as described above, 4,4′-(4,4′-isopropylidenediphenoxy)-bis(phthalic acid anhydride) represented by the following formula (IV) from the viewpoint that it is possible to obtain an adhesive film excellent in adhesion force, satisfactory in the balance between the individual properties and high in reliability. In this case the amount of the tetracarboxylic acid dianhydride represented by formula (IV) is preferably 60 mol % or more and more preferably 70 mol % or more of the whole of the tetracarboxylic acid dianhydrides.

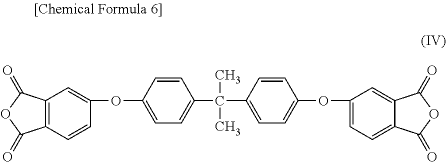

Examples of the other tetracarboxylic acid dianhydrides used as the raw material for the polyimide resin include: 4,4′-(ethane-1,2-diylbis(oxycarbonyl))diphthalic acid anhydride, 4,4′-(decane-1,10-diylbis(oxycarbonyl))diphthalic anhydride, 1,4-bis(2-hydroxyhexafluoroisopropyl)benzenebis(trimelliticacid dianhydride), 1,3-bis(2-hydroxyhexafluoroisopropyl)benzenebis(trimelliticacid dianhydride), 4,4′-(propane-1,3-diylbis(oxycarbonyl))diphthalic acid anhydride, 4,4′-(butane-1,4-diylbis(oxycarbonyl))diphthalic acid anhydride, 4,4′-(pentane-1,5-diylbis(oxycarbonyl))diphthalic acid anhydride, 4,4′-(hexane-1,6-diylbis(oxycarbonyl))diphthalic acid anhydride, 4,4′-(heptane-1,7-diylbis(oxycarbonyl))diphthalic acid anhydride, 4,4′-(octane-1,8-diylbis(oxycarbonyl))diphthalic acid anhydride, 4,4′-(nonane-1,9-diylbis(oxycarbonyl))diphthalic acid anhydride, 4,4′-(undecane-1,11-diylbis(oxycarbonyl))diphthalic acid anhydride and 4,4′-(dodecane-1,12-diylbis(oxycarbonyl))diphthalic acid anhydride, and these can be used each alone, or in combinations of two or more thereof. Because these tetracarboxylic acid dianhydrides have hydrolyzable substituents, it is preferable to use these tetracarboxylic acid dianhydrides in a range not exceeding 40 mol % of the whole of the tetracarboxylic acid dianhydrides.

The condensation reaction between the tetracarboxylic acid dianhydride and the diamine is performed in an organic solvent. In this case, it is preferable to use the tetracarboxylic acid dianhydride and the diamine in equal numbers of moles or approximately equal numbers of moles; however, the acid-amine ratio may be deviated within a range of ±10 mol %, and the order of addition of the individual components is optional.

Examples of the organic solvent used for the synthesis include dimethylacetamide, dimethylformamide, N-methyl-2-pyrrolidone, dimethyl sulfoxide, hexamethylphosphoryl amide, m-cresol and o-chlorophenol.

The reaction temperature of the condensation reaction is preferably 150° C. or lower and more preferably 0 to 120° C. When the solubility of the diamine represented by formula (II) is insufficient, there occurs a preferable case where a uniform reaction solution is obtained by heating to 50° C. or higher as the case may be. As the reaction proceeds, the viscosity of the reaction solution gradually increases. In this stage, a polyamic acid, which is a precursor of the polyimide resin, is produced.

It is possible to obtain the polyimide resin by dehydration cyclization of the above-described reaction product (polyamic acid). The dehydration cyclization can be performed by using a method in which a heat treatment is performed at 120° C. to 250° C. or a chemical method. In the case of the method in which a heat treatment is performed at 120° C. to 250° C., it is preferable to perform the dehydration cyclization while the water produced by the dehydration reaction is being removed to outside the reaction system. In this case, the water may be removed by azeotropic distillation by using benzene, toluene, xylene or the like.

In the present DESCRIPTION, the term polyimide resin includes polyimide and the precursors thereof. Among the precursors of polyimide are, in addition to polyamic acid, the compounds in which polyamic acid is partially imidized. The synthesis of polyamic acid and the dehydration cyclization of polyamic acid by heat treatment are not necessarily required to be definitely separated into distinct steps.

In the case where the dehydration cyclization is performed by the chemical method, usable as a cyclizing agent are: acid anhydrides such as acetic acid anhydride, propionic acid anhydride and benzoic acid anhydride; carbodiimide compounds such as dicyclohexylcarbodiimide; and others. In this case, where necessary, there may be further used cyclization catalysts such as pyridine, isoquinoline, trimethylamine, aminopyridine and imidazole. It is preferable that the cyclization agent or the cyclization catalyst is used in a range from 1 to 8 mol in relation to 1 mol of the tetracarboxylic acid dianhydride.

The synthesized polyimide resin can be made to be solid by removing the greater part of the solvent used in the reaction. Examples of the method for this purpose include a method in which the solvent used for the reaction is evaporated at an appropriate temperature and an appropriate pressure to dry the resin.

Examples of the method for this purpose also include a method in which the reaction solution is added to a poor solvent having an appropriately low solubility of the resin to precipitate the resin, then the poor solvent containing the solvent used for the reaction is removed by filtration or sedimentation, and then the resin is dried; this method is preferable because in this way, this method can also remove the impurities in the resin, in particular, substances low in volatility.

The poor solvent is not particularly limited as long as the solubility of the polyimide resin in the poor solvent is low; however, from the viewpoint of easy handleability, examples of the poor solvent include water and lower alcohols having 4 or less carbon atoms, and these can be used each alone or in combinations of two or more thereof. A good solvent may also be mixed in such a range that the mixed solvent as a whole can precipitate the resin.

When no impurities are present in the reaction system or the amounts of the impurities are small to such an extent that the impurities do not affect the properties, the solvent used for the reaction is used as it is in such a way that the solvent used for the reaction is used as the solvent used for the below-described production of the adhesive film. In this case, there is no need for removing the solvent used for the reaction, and hence the step is short and this case is preferable with respect to the production cost.

When the polyimide resin is combined with other resins, in consideration of the properties of the adhesive film such as the adhesiveness, the heat resistance and the Tg, the adhesive layer includes the polyimide resin in an amount of preferably 30% by mass or more, more preferably 50% by mass or more and furthermore preferably 70% by mass or more with reference to the total mass of the adhesive layer.

The chemical structure of the acrylic resin constituting the adhesive layer is not particularly limited; however, the acrylic resin may be a homopolymer of a (meth)acrylic acid ester, and a copolymer between a (meth)acrylic acid ester and the monomer selected from (meth)acrylic acid esters, acrylonitrile, acrylamide, vinyl monomer, styrene, vinyl ether, butadiene and maleimide. In particular, the copolymer of ethyl (meth)acrylate, glycidyl (meth)acrylate and acrylonitrile and the copolymer of butyl (meth)acrylate, glycidyl (meth)acrylate and acrylonitrile are preferable. Examples of the commercially available products of such acrylic resins include HTR-860P-3 manufactured by Teikoku Kagaku Sangyo Co., Ltd.

The adhesive layer may include a thermosetting resin for the purpose of improving the strength under high temperatures. The term thermosetting resin means a resin which forms three dimensional network structure by heating and thus becomes cured. As the thermosetting resin, heretofore known thermosetting resins can be used, and the thermosetting resin is not particularly limited; however, from the viewpoint of the convenience (easy availability of high purity products, abundance in types and easiness in reaction control) as the peripheral material for semiconductors, preferable among others are epoxy resin and imide compounds having two or more thermosetting imide groups.

The epoxy resin constituting the adhesive layer is not particularly limited as long as the epoxy resin is a compound having one or more epoxy groups in one molecule thereof. Examples of the epoxy resin include: alkyl monoglycidyl ether, phenyl glycidyl ether, alkylphenol monoglycidyl ether, 3-glycidoxypropyltrimethoxysilane, 3-glycidoxypropylmethyldimethoxysilane, 1-(3-glycidoxypropyl)-1,1,3,3,3-pentamethyldisiloxane, alkylmonoglycidyl ester, bisphenol A type epoxy resins [AER-X8501 (trade name, Asahi Kasei Epoxy Co., Ltd.), R-301 (trade name, Mitsui Chemicals, Inc.) and YL-980 (trade name, Japan Epoxy Resin Co., Ltd.)], a bisphenol F type epoxy resin [YDF-170 (trade name, Tohto Kasei Co., Ltd.)], a bisphenol AD type epoxy resin [R-1710 (trade name, Mitsui Chemicals, Inc.)], phenol novolac type epoxy resins [N-730S (trade name, Dainippon Ink and Chemicals Inc.) and Quatrex-2010 (trade name, Dow Chemical Inc.)], a bisphenol S type epoxy resin, cresol novolac type epoxy resins [YDCN-702S (trade name, Tohto Kasei Co., Ltd.) and EOCN-100 (trade name, Nippon Kayaku Co., Ltd.)], multifunctional epoxy resins [EPPN-501 (trade name, Nippon Kayaku Co., Ltd.), TACTIX-742 (trade name, Dow Chemical Inc.), VG-3010 (trade name, Mitsui Chemicals Inc.) and 1032S (trade name, Japan Epoxy Resin Co., Ltd.)], an epoxy resin having naphthalene skeleton [HP-4032 (trade name, Dainippon Ink and Chemicals Inc.)], dicyclo type epoxy resins [EP-4088S (trade name, Asahi Denka Kogyo Co., Ltd.) and XD-1000-L (trade name, Nippon Kayaku Co., Ltd.)], alicyclic epoxy resins [EHPE-3150, CEL-3000 (trade names, Daicel Chemical Industries, Ltd.), DME-100 (trade name, New Japan Chemical Co., Ltd.) and EX-216L (trade name, Nagase ChemteX Corp.)], aliphatic epoxy resins [W-100 (trade name, New Japan Chemical Co., Ltd.) and YH-300 (trade name, Tohto Kasei Co., Ltd.)], epoxidized polybutadienes [PB-3600 (trade name, Daicel Chemical Industries, Ltd.) and E-1000-3.5 (trade name, Nippon Petrochemicals Co., Ltd.)], epoxidized vegetable oils [S-300K and L-500 (trade names, Daicel Chemical Industries, Ltd.)], amine-type epoxy resins [ELM-100 (trade name, Sumitomo Chemical Co., Ltd.), YH-434L (trade name, Tohto Kasei Co., Ltd.), TETRAD-X, TETRAD-C (trade names, Mitsubishi Gas Chemical Company, Inc.), GOT and GAN (trade names, Nippon Kayaku Co., Ltd.)], ethylene/propylene glycol-modified bisphenol type epoxy resins [EP-4000S (trade name, Asahi Denka Kogyo Co., Ltd.) and BEO-60E (trade name, New Japan Chemical Co., Ltd.)], hydrogenated bisphenol type epoxy resins [EXA-7015 (trade name, Nippon Kayaku Co., Ltd.) and ST-5080 (trade name, Tohto Kasei Co., Ltd.)], a resorcin type epoxy resin [Denacol EX-201 (trade name, Nagase ChemteX Corp.)], an epoxy resin having a catechol skeleton [EXA-7120 (trade name, Dainippon Ink and Chemicals Inc.)], a neopentyl glycol type epoxy resin [Denacol EX-211 (trade name, Nagase ChemteX Corp.], a hexanedinel glycol type epoxy resin [Denacol EX-212 (Nagase ChemteX Corp.)], ethylene/propylene glycol type epoxy resins [Denacol EX-810, 811, 850, 851, 821, 830, 832, 841 and 861 (trade names, Nagase ChemteX Corp.)], a biphenyl type epoxy resin [YX-4000H (Japan Epoxy Resin Co., Ltd.)], epoxy resins represented by the following formula [E-XL-24 and E-XL-3L (trade names, Mitsui Chemicals, Inc.)] (in the formula, a represents an integer of 0 to 5),

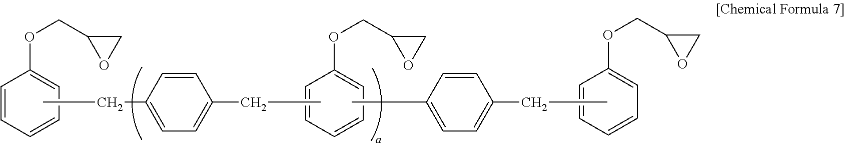

urethane-modified epoxy resins [EPU-15 and EPU-18 (trade names, Asahi Denka Kogyo Co., Ltd.)], rubber-modified epoxy resins [EPR-4032 and EPR-1309 (trade names, Asahi Denka Kogyo Co., Ltd.)], chelate-modified epoxy resins [EP-49-10 and EPU-78-11 (trade names, Asahi Denka Kogyo Co., Ltd.)] and glycidyl ester type epoxy resins [YD-171, YD-172 (trade names, Tohto Kasei Co., Ltd.) and AK-601 (trade name, Nippon Kayaku Co., Ltd.)].

It is preferable to use, among these, at least one epoxy resin selected from the group consisting of the bisphenol A type resin, the bisphenol F type epoxy resin, the bisphenol AD type epoxy resin, the phenol novolac type resin, the cresol novolac type resin and the alicyclic epoxy resin. These epoxy resins can be used each alone or in combinations of two or more thereof.

Among these epoxy resins, in particular, the tri- or higher-functional epoxy resins are preferable because the effects of such epoxy resins in improving the properties are high. Examples of the tri- or higher-functional epoxy resins include the novolac type epoxy resin represented by the following formula (V), tri-functional type (or quadric-functional type) glycidyl ethers and tri-functional type (or quadric-functional type) glycidyl amines. In formula (V), a plurality of R³s each independently represent a phenyl group which may have a hydrogen atom, an alkyl group having 1 to 5 carbon atoms or a substituent, and p is an integer of 1 to 20.

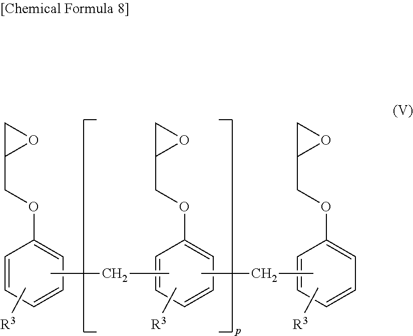

Examples of the novolac type epoxy resin represented by the above formula (V) include a glycidyl ether of the cresol novolac resin and a glycidyl ether of the phenol novolac resin. These are preferable because these are high in the crosslinking densities of the cured products thereof and can enhance the adhesive strength of the film under high temperatures, and these can be used each alone or in combinations of two or more thereof.

The adhesive layers 21 and 22 may contain a curing agent to be used in combination with the epoxy resins.

Examples of the epoxy resin curing agent include phenolic compounds, aliphatic amines, alicyclic amines, aromatic polyamines, polyamide, aliphatic acid anhydrides, alicyclic acid anhydrides, aromatic acid anhydrides, dicyandiamide, organic acid dihydrazides, boron trifluoride-amine complexes, imidazoles and tertiary amines. Among these, the phenolic compounds are preferable, and phenolic compounds having at least two phenolic hydroxyl groups are more preferable.

Examples of the phenolic compounds having at least two phenolic hydroxyl groups include phenol novolac resin, cresol novolac resin, t-butylphenol novolac resin, dicyclopentadiene cresol novolac resin, dicyclopentadiene phenol novolac resin, xylylene-modified phenol novolac resin, naphthol novolac resin, trisphenol novolac resin, tetrakisphenol novolac resin, bisphenol A novolac resin, poly-p-vinylphenol resin and phenol aralkyl resin. Preferable among these are the resins each having a number average molecular weight falling within a range from 400 to 1500. Herewith, it is possible to effectively reduce the outgas to be a causes for contamination of the chip surface, the apparatus and the like at the time of heating for package assembling.

Among the examples cited above, preferable as the epoxy resin curing agent are the naphthol novolac resin and the trisphenol novolac resin because it is possible to reduce the outgas to be a cause for contamination of the chip surface, the apparatus and the like or a cause for odor at the time of heating for package assembling.

The naphthol novolac resin is, for example, a naphthol-based compound having three or more aromatic rings in the molecule thereof, represented by the following formula (VI) or the following formula (VII).

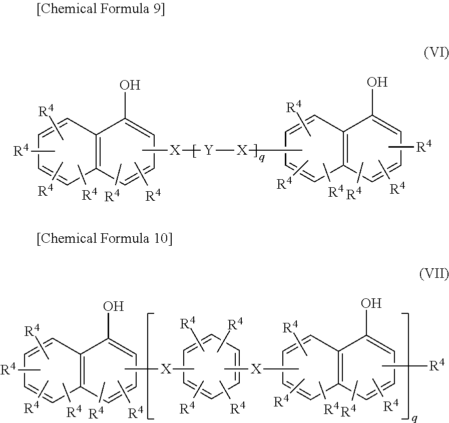

In formula (VI) and formula (VII), a plurality of R⁴s each represent hydrogen, an alkyl group having 1 to 10 carbon atoms, a phenyl group or a hydroxyl group, q is an integer of 1 to 10, X represents a divalent organic group and Y represents a divalent substituent selected from the following formulas.

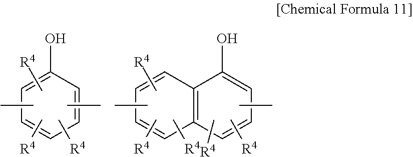

Specific examples of the substituent X in formulas (VI) and (VII) include the divalent substituents represented by the following formulas.

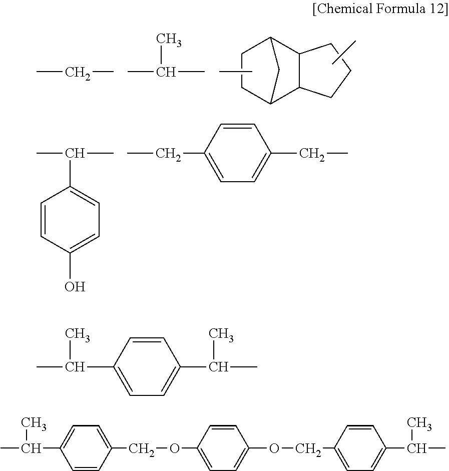

Specific examples of the naphthol-based compound include the xylylene-modified naphthol novolac represented by the following formula (VIII) or (IX), and the naphthol novolac represented by the following formula (X), based on the condensation with p-cresol. In formulas (VIII) to (X), r is an integer of 1 to 10.

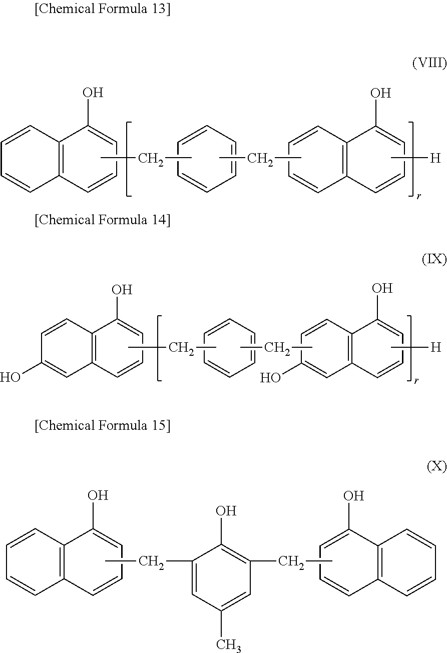

The trisphenol-based compound may be trisphenol novolac resins having three hydroxyphenyl groups. Preferable among such resins are the compounds represented by the following formula (XI).

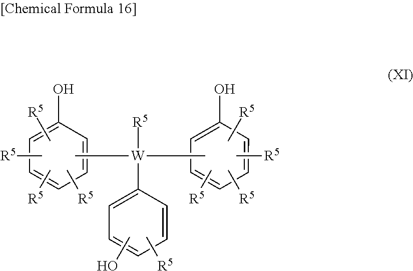

In formula (XI), a plurality of R⁵s each independently represent a hydrogen atom, an alkyl group having 1 to 10 carbon atoms, a phenyl group or a hydroxyl group, and W represents a tetravalent organic group selected from the following formulas.

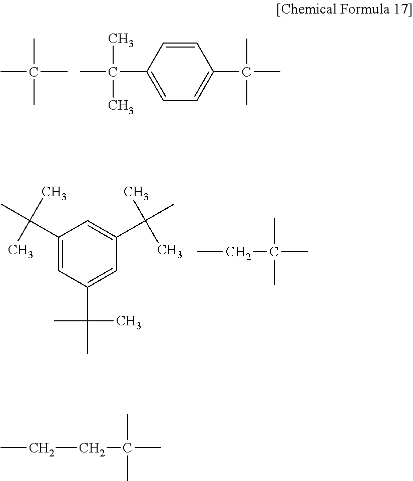

Specific examples of the trisphenol-based compound include: 4,4′,4″-methylidene trisphenol, 4,4′-(1-(4-(1-(4-hydroxyphenyl)-1-methylethyl)phenyl)ethylidene)bisphenol, 4,4′,4″-ethylidene tris(2-methylphenol), 4,4′,4″-ethylidene trisphenol, 4,4′-((2-hydroxyphenyl)methylene)bis(2-methylphenol), 4,4′-((4-hydroxyphenyl)methylene)bis(2-methylphenol), 4,4′-((2-hydroxyphenyl)methylene)bis(2,3-dimethylphenol), 4,4′-((4-hydroxyphenyl)methylene)bis(2,6-dimethylphenol), 4,4′-((3-hydroxyphenyl)methylene)bis(2,3-dimethylphenol), 2,2′-((2-hydroxyphenyl)methylene)bis(3,5-dimethylphenol), 2,2′-((4-hydroxyphenyl)methylene)bis(3,5-dimethylphenol), 2,2′-((2-hydroxyphenyl)methylene)bis(2,3,5-trimethylphenol), 4,4′-((2-hydroxyphenyl)methylene)bis(2,3,6-trimethylphenol), 4,4′-((3-hydroxyphenyl)methylene)bis(2,3,6-trimethylphenol), 4,4′-((4-hydroxyphenyl)methylene)bis(2,3,6-trimethylphenol), 4,4′-((2-hydroxyphenyl)methylene)bis(2-cyclohexyl-5-methylphenol), 4,4′-((3-hydroxyphenyl)methylene)bis(2-cyclohexyl-5-methylphenol), 4,4′-((4-hydroxyphenyl)methylene)bis(2-cyclohexyl-5-methylphenol), 4,4′-((3,4-dihydroxyphenyl)methylene)bis(2-methylphenol), 4,4′-((3,4-dihydroxyphenyl)methylene)bis(2,6-dimethylphenol), 4,4′-((3,4-dihydroxyphenyl)methylene)bis(2,3,6-trimethylphenol), 4-(bis(3-cyclohexyl-4-hydroxy-6-methylphenyl)methyl)-1,2-benzenediol, 4,4′-((2-hydroxyphenyl)methylene)bis(3-methylphenol), 4,4′,4″-(3-methyl-1-pronanyl-3-ylidene)trisphenol, 4,4′-((2-hydroxyphenyl)methylene)bis(2-methylphenol), 4,4′-((3-hydroxyphenyl)methylene)bis(2-methylphenol), 4,4′-((4-hydroxyphenyl)methylene)bis(2-methylphenol), 2,2′-((3-hydroxyphenyl)methylene)bis(3,5,6-trimethylphenol), 2,2′-((4-hydroxyphenyl)methylene)bis(3,5,6-trimethylphenol), 4,4′-((2-hydroxyphenyl)methylene)bis(2-cyclohexylphenol), 4,4′-((3-hydroxyphenyl)methylene)bis(2-cyclohexylphenol), 4,4′-(1-(4-(1-(4-hydroxy-3,5-dimethylphenyl)-1-methylethyl)phenyl)ethylidene)bis(2,6-dimethylphenol), 4,4′,4″-methylidinetris(2-cyclohexyl-5-methylphenol), 4,4′-(1-(4-(1-(3-cyclohexyl-4-hydroxyphenyl)-1-methylethyl)phenyl)ethylidene)bis(2-cyclohexylphenol), 2,2′-((3,4-dihydroxyphenyl)methylene)bis(3,5-dimethylphenol), 4,4′-((3,4-dihydroxyphenyl)methylene)bis(2-(methylethyl)phenol), 2,2′4(3,4-dihydroxyphenyl)methylene)bis(3,5,6-trimethylphenol), 4,4′4(3,4-dihydroxyphenyl)methylene)bis(2-cyclohexylphenol) and α,α′,α″-tris(4-hydroxyphenyl)-1,3,5-triisoporpylbenzene. These can be used each alone or in combinations of two or more thereof.

Examples of the curing agent includes: phenol compounds such as phenol novolac resins [H-1 (trade name, Meiwa Plastic Industries, Ltd.) and VR-9300 (trade name, Mitsui Chemicals, Inc.)], a phenol aralkyl resin [XL-225 (trade name, Mitsui Chemicals, Inc.)], an allylated phenol novolac resin [AL-VR-9300 (trade name, Mitsui Chemicals, Inc.)], a specific phenol resin represented by the following formula [pp-700-300 (trade name, manufactured by Nippon Petrochemicals Co., Ltd.)] (in the formula, R1 represents an alkyl group having 1 to 6 carbon atoms such as a methyl or ethyl group, R2 represents hydrogen or an alkyl group having 1 to 6 carbon atoms such as a methyl or ethyl group, and b represents an integer of 2 to 4),

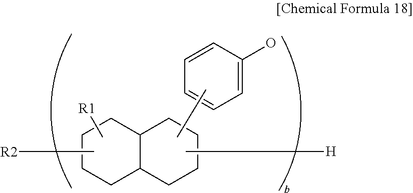

bisphenol F, bisphenol A, bisphenol AD, bisphenol S, allylated bisphenol F, allylated bisphenol A, allylated bisphenol AD, allylated bisphenol S and multifunctional phenols [p-CR, TrisP-PHBA, MTPC and TrisP-RS (trade names, Honshu Chemical Industry Co., Ltd.)]; amine compounds such as o-phenylenediamine, m-phenylenediamine, p-phenylenediamine, 3,3′-diaminodiphenyl ether, 3,4′-diaminodiphenyl ether, 4,4′-diaminodiphenyl ether, 3,3′-diaminodiphenylmethane, 3,4′-diaminodiphenylmethane, 4,4′-diaminodiphenylmethane, 3,3′-diaminodiphenyldifluoromethane, 3,4′-diaminodiphenyldifluoromethane, 4,4′-diaminodiphenyldifluoromethane, 3,3′-diaminodiphenyl sulfone, 3,4′-diaminodiphenyl sulfone, 4,4′-diaminodiphenyl sulfone, 3,3′-diaminodiphenyl sulfide, 3,4′-diaminodiphenyl sulfide, 4,4′-diaminodiphenyl sulfide, 3,3′-diaminodiphenyl ketone, 3,4′-diaminodiphenyl ketone, 4,4′-diaminodiphenyl ketone, 2,2-bis(3-aminophenyl)propane, 2,2′-(3,4′-diaminodiphenyl)propane, 2,2-bis(4-aminophenyl)propane, 2,2-bis(3-aminophenyl)hexafluoropropane, 2,2-(3,4′-diaminodiphenyl)hexafluoropropane, 2,2-bis(4-aminophenyl)hexafluoropropane, 1,3-bis(3-aminophenoxy)benzene, 1,4-bis(3-aminophenoxy)benzene, 1,4-bis(4-aminophenoxy)benzene, 3,3′-(1,4-phenylenebis(1-methylethylidene))bisaniline, 3,4′-(1,4-phenylenebis(1-methylethylidene))bisaniline, 4,4′-(1,4-phenylenebis(1-methylethylidene))bisaniline, 2,2-bis(4-(3-aminophenoxy)phenyl)propane, 2,2-bis(4-(4-aminophenoxy)phenyl)propane, 2,2-bis(4-(3-aminophenoxy)phenyl)hexafluoropropane, 2,2-bis(4-(4-aminophenoxy)phenyl)hexafkuoropropane, bis(4-(3-aminophenoxy)phenyl)sulfide, bis(4-(4-aminophenoxy)phenyl)sulfide, bis(4-(3-aminophenoxy)phenyl)sulfone, bis(4-(4-aminophenoxy)phenyl)sulfone, 1,2-diaminoethane, 1,3-diaminopropane, 1,4-diaminobutane, 1,5-diaminopentane, diethylenetriamine, triethylenetetramine, diethylaminopropylamine, 1,1,3,3-tetramethyl-1,3-bis(4-aminophenyl)disiloxane, 1,1,3,3-tetraphenoxy-1,3-bis(4-aminoethyl)disiloxane, 1,1,3,3-tetraphenyl-1,3-bis(2-aminoethyl)disiloxane, 1,1,3,3-tetraphenyl-1,3-bis(3-aminopropyl)disiloxane, 1,1,3,3-tetramethyl-1,3-bis(2-aminoethyl)disiloxane, 1,1,3,3-tetramethyl-1,3-bis(3-aminopropyl)disiloxane, 1,1,3,3-tetramethyl-1,3-bis(3-aminobutyl)disiloxane, 1,3-diemthyl-1,3-dimethoxy-1,3-bis(4-aminobutyl)disiloxane, 1,1,3,3,5,5-hexamethyl-1,5-bis(4-aminophenyl)trisiloxane, 1,1,5,5-tetraphenyl-3,3-dimethyl-1,5-bis(3-aminopropyl)trisiloxane, 1,1,5,5-tetraphenyl-3,3-dimethoxy-1,5-bis(4-aminobutyl)trisiloxane, 1,1,5,5-tetraphenyl-3,3-dimethoxy-1,5-bis(5-aminopentyl)trisiloxane, 1,1,5,5-tetramethyl-3,3-dimethoxy-1,5-bis(2-aminoethyl)trisiloxane, 1,1,5,5-tetramethyl-3,3-dimethoxy-1,5-bis(4-aminobutyl)trisiloxane, 1,1,5,5-tetramethyl-3,3-dimethoxy-1,5-bis(5-aminopentyl)trisiloxane, 1,1,3,3,5,5-hexamethyl-1,5-bis(3-aminopropyl)trisiloxane, 1,1,3,3,5,5-hexaethyl-1,5-bis(3-aminopropyl)trisiloxane, 1,1,3,3,5,5-hexapropyl-1,5-bis(3-aminopropyl)trisiloxane, triethylamine, benzyldimethylamine, α-methylbenzyldimethylamine, trisdimethylaminomethylphenol, piperidine, methanediamine, boron trifluoride monoethylamine, 1,8-diazabicyclo [5.4.0]-undecene-7, 6-butyl-1,8-diazabicyclo [5.4.0]-undecene-7 and 1,5-diazabicyclo [4.3.0]-nonene-5; dicyandiamide; dibasic acid dihydrazides represented by the following formula [ADH, PDH and SDH (trade names, all manufactured by Nippon Hydrazine Industries Co., Ltd.)] (in the formula, R3 represents a divalent aromatic group such as a m-phenylene group or a p-phenylene group, or a linear or branched alkylene group having 2 to 12 carbon atoms),

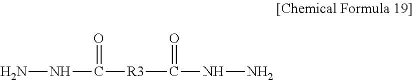

a microcapsule type curing agent composed of a reaction product between an epoxy resin and an amine compound [Novacure (trade name, manufactured by Asahi Chemical Industry Co., Ltd.)]; urea compounds such as U-CAT3502T and U-CAT3503N (trade names, San-Apro, Ltd.); acid anhydrides such as phthalic acid anhydride, maleic acid anhydride, citraconic acid anhydride, itaconic acid anhydride, succinic acid anhydride, dodecylsuccinic acid anhydride, tetrahydrophthalic acid anhydride, hexahydrophthalic acid anhydride, 3 or 4-methyl-1,2,3,6-tetrahydrophthalic acid anhydride, 3 or 4-methylhexahydrophthalic acid anhydride, bicyclo [2.2.1]hept-5-ene-2,3-dicarboxylic acid anhydride, methylbicyclo [2.2.1]hept-5-ene-2,3-dicarboxylic acid anhydride, pyromellitic acid dianhydride, 3,3′,4,4′-diphenyltetracarboxylic acid dianhydride, 2,2′,3,3′-diphenyltetracarboxylic acid dianhydride, 2,2-bis(3,4-dicarboxyphenyl)propane dianhydride, 2,2-bis(2,3-dicarboxyphenyl)propane dianhydride, 1,1-bis(2,3-dicarboxyphenyl)ethane dianhydride, 1,1-bis(3,4-dicarboxyphenyl)ethane dianhydride, bis(2,3-dicarboxyphenyl)methane dianhydride, bis(3,4-dicarboxyphenyl)methane dianhydride, bis(3,4-dicarboxyphenyl)sulfone dianhydride, 3,4,9,10-perylenetetracarboxylic acid dianhydride, bis(3,4-dicarboxyphenyl)ether dianhydride, benzene-1,2,3,4-tetracarboxylic acid dianhydride, 3,4,3′,4′-benzophenonetetracarboxylic acid dianhydride, 2,3,2′,3′-benzophenonetetracarboxylic acid dianhydride, 2,3,3′,4′-benzophenonetetracarboxylic acid dianhydride, 1,2,5,6-naphthalenetetracarboxylic acid dianhydride, 2,3,6,7-naphthalenetetracarboxylic acid dianhydride, 1,2,4,5-naphthalenetetracarboxylic acid dianhydride, 1,4,5,8-naphthalenetetracarboxylic acid dianhydride, 2,6-dichloronaphthalene-1,4,5,8-tetracarboxylic acid dianhydride, 2,7-dichloronaphthalene-1,4,5,8-tetracarboxylic acid dianhydride, 2,3,6,7-tetrachloronaphthalene-1,4,5,8-tetracarboxylic acid dianhydride, phenanthrene-1,8,9,10-tetracarboxylic acid dianhydride, pyrazine-2,3,5,6-tetracarboxylic acid dianhydride, thiophene-2,3,4,5-tetracarboxylic acid dianhydride, 2,3,3′,4′-biphenyltetracarboxylic acid dianhydride, 3,4,3′,4′-biphenyltetracarboxylic acid dianhydride, 2,3,2′,3′-biphenyltetracarboxylic acid dianhydride, bis(3,4-dicarboxyphenyl)dimethylsilane dianhydride, bis(3,4-dicarboxyphenyl)methylphenylsilane dianhydride, bis(3,4-dicarboxyphenyl)diphenylsilane dianhydride, 1,4-bis(3,4-dicarboxyphenyldimethylsilyl)benzene dianhydride, 1,3-bis(3,4-dicarboxyphenyl)-1,1,3,3-tetramethyldicyclohexane dianhydride, p-phenylenebis(trimellitate anhydride), ethylenetetracarboxylic acid dianhydride, 1,2,3,4-butanetetracarboxylic acid dianhydride, decahydronaphthalene-1,4,5,8-tetracarboxylic acid dianhydride, 4,8-dimethyl-1,2,3,5,6,7-hexahydronaphthalene-1,2,5,6-tetracarboxylic acid dianhydride, cyclopentane-1,2,3,4-tetracarboxylic acid dianhydride, pyrrolidine-2,3,4,5-tetracarboxylic acid dianhydride, 1,2,3,4-cyclobutanetetracarboxylic acid dianhydride, bis(exo-bicyclo[2.2.1]heptane-2,3-dicarboxylic acid dianhydride) sulfone, bicyclo-(2.2.2)-oct-7-ene-2,3,5,6-tetracarboxylic acid dianhydride, 2,2-bis(3,4-dicarboxyphenyl)hexafluoropropane dianhydride, 2,2-bis[4-(3,4-dicarboxyphenoxy)phenyl]hexafluoropropane dianhydride, 4,4′-bis(3,4-dicarboxyphenoxy)diphenyl sulfide dianhydride, 4,4′-(4,4′-isopropylidenediphenoxy)-bis(phthalic acid anhydride), 4,4′-[decane-1,10-diylbis(oxycarbonyl)]diphthalic acid anhydride, 1,4-bis(2-hydroxyhexafluoroisopropyl)benzenebis(trimellitic acid dianhydride), 1,3-bis(2-hydroxyhexafluoroisopropyl)benzenebis(trimellitic acid dianhydride), 5-(2,5-dioxotetrahydrofuryl)-3-methyl-3-cyclohexene-1,2-dicarboxylic acid dianhydride and tetrahydrofuran-2,3,4,5-tetracarboxylic acid dianhydride; cationic polymerization catalysts such as KT-990, CP-77 (trade names, Asahi Denka Kogyo Co., Ltd.), SI-L85 and SI-L145 (trade names, Sanshin Chemical Industry Co., Ltd.); polymercapto compounds; and polyamide compounds. These curing agents may be used in appropriate combinations of two or more thereof.

When the epoxy resin and the epoxy resin curing agent are used, the proportion of the epoxy resin is preferably 1 to 200 parts by mass, more preferably 1 to 100 parts by mass and furthermore preferably 1 to 90 parts by mass in relation to 100 parts by mass of the polyimide resin. When this proportion exceeds 200 parts by mass, the film formability tends to decrease. The proportion of the epoxy resin curing agent is preferably 0.1 to 150 parts by mass, more preferably 0.1 to 120 parts by mass and furthermore preferably 10 to 100 parts by mass in relation to 100 parts by mass of the epoxy resin. When this proportion exceeds 150 parts by mass, the curability tends to decrease.

The adhesive layers 21 and 22 may contain, where necessary, an epoxy resin curing accelerator. The curing accelerator is not particularly limited as long as the curing accelerator is a compound to be used for curing the epoxy resin; examples of the curing accelerator include imidazoles, dicyandiamide derivatives, dicarboxylic acid dihydrazides, triphenylphosphine, tetraphenylphosphonium tetraphenylborate, 2-ethyl-4-methylimidazole-tetraphenylborate and 1,8-diazabicyclo[5.4.0]undecane-7-tetraphenylborate. These can be used each alone or in combinations of two or more thereof. Examples of the curing accelerator include organic boron chlorides [EMZ.K and TPPK (trade names, Hokko Chemical Industry Co., Ltd.)] and imidazoles [Curezole, 2P4 MHZ, C17Z and 2PZ-OK (trade names, Shikoku Chemicals Corp.)].

The amount of the curing accelerator is preferably 0.01 to 50 parts by mass, more preferably 0.01 to 20 parts by mass and furthermore preferably 0.1 to 10 parts by mass in relation to 100 parts by mass of the thermosetting resin. When the amount of the curing accelerator exceeds 50 parts by mass, the storage stability tends to decrease, and when the amount of the curing accelerator is less than 0.01 part by mass, the effect of the curing acceleration tends to decrease.

Examples of the imide compound having two or more thermosetting imide groups include orthobismaleimidebenzene, metabismaleimidebenzene, parabismaleimidebenzene, 1,4-bis(p-maleimidecumyl)benzene and 1,4-bis(m-maleimidecumyl)benzene.

In addition to these, examples of the concerned imide compound also include the imide compounds represented by the following formulas (XII) to (XV). These can be used each alone or in combinations of two or more thereof.

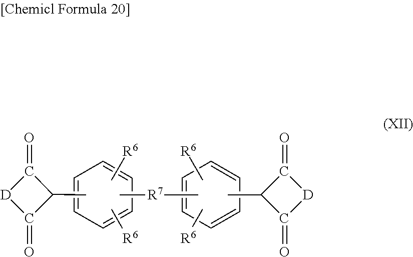

In formula (XII), R⁷ represents O, CH₂, CF₂, SO₂, S, CO, C(CH₃)₂ or C(CF₃)₂, four R⁶s each independently represent a hydrogen atom, an alkyl group having 1 to 6 carbon atoms, an alkoxy group having 1 to 6 carbon atoms, a fluorine atom, a chlorine atom or a bromine atom, and D represents a dicarboxylic acid residue having an ethylenically unsaturated double bond.

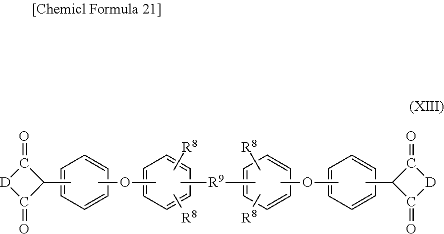

In formula (XIII), R⁹ represents O, CH₂, CF₂, SO₂, S, CO, C(CH₃)₂ or C(CF₃)₂, four R⁸s each independently represent a hydrogen atom, an alkyl group having 1 to 6 carbon atoms, an alkoxy group having 1 to 6 carbon atoms, a fluorine atom, a chlorine atom or a bromine atom, and D represents a dicarboxylic acid residue having an ethylenically unsaturated double bond.

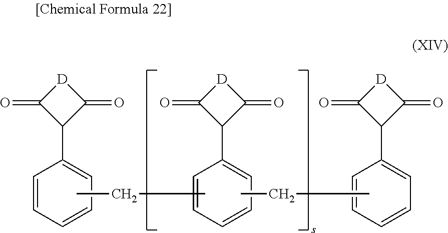

In formula (XIV), s is an integer of 0 to 4 and D represents a dicarboxylic acid residue having an ethylenically unsaturated double bond.

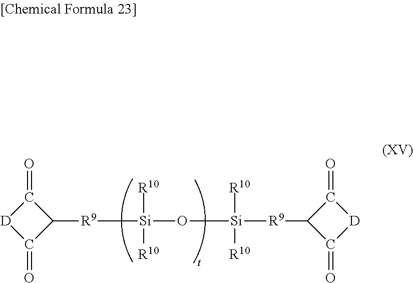

In formula (XV), two R⁹s each independently represents a divalent hydrocarbon group, a plurality of R¹⁰s each independently represent a monovalent hydrocarbon group, D represents a dicarboxylic acid residue having an ethylenically unsaturated double bond, and t is an integer of 1 or more.

In each of the structural formulas, examples of the dicarboxylic acid residue, represented by D, having an ethylenically unsaturated double bond include the maleic acid residue and the citraconic acid residue.

The amount of the imide compound is preferably 0 to 200 parts by mass, more preferably 0 to 150 parts by mass and furthermore preferably 1 to 100 parts by mass in relation to 100 parts by mass of the polyimide resin. When the amount of the imide compound exceeds 200 parts by mass, the film formability tends to decrease.

Examples of the imide compound represented by the above formula (XII) include 4,4-bismaleimidediphenyl ether, 4,4-bismaleimidediphenylmethane, 4,4-bismaleimide-3,3′-dimethyldiphenylmethane, 4,4-bismaleimidediphenyl sulfone, 4,4-bismaleimidediphenyl sulfide, 4,4-bismaleimidediphenylketone, 2,2′-bis(4-maleimidephenyl)propane, 4,4-bismaleimidediphenylfluoromethane and 1,1,1,3,3,3-hexafluoro-2,2-bis(4-maleimidephenyl)propane.

Examples of the imide compound represented by the above formula (XIII) include bis(4-(4-maleimidephenoxy)phenyl)ether, bis(4-(4-maleimidephenoxy)phenyl)methane, bis(4-(4-maleimidephenoxy)phenyl)fluoromethane, bis(4-(4-maleimidephenoxy)phenyl)sulfone, bis(4-(3-maleimidephenoxy)phenyl)sulfone, bis(4-(4-maleimidephenoxy)phenyl)sulfide, bis(4-(4-maleimidephenoxy)phenyl)ketone, 2,2-bis(4-(4-maleimidephenoxy)phenyl)propane and 1,1,1,3,3,3-hexafluoro-2,2-bis(4-(4-maleimidephenoxy)phenyl)propane.

For the purpose of accelerating the curing of these imide compounds, a radical polymerization initiator may also be used. Examples of the radical polymerization initiator include acetylcyclohexylsulfonyl peroxide, isobutyryl peroxide, benzoyl peroxide, octanoyl peroxide, acetyl peroxide, dicumyl peroxide, cumene hydroperoxide and azobisisobutyronitrile. In this case, the used amount of the radical polymerization initiator is preferably about 0.01 to 1.0 part by mass in relation to 100 parts by mass of the imide compound.

By making the adhesive layer contain a thermosetting resin, the shear adhesion force at high temperatures can be increased. However, when a thermosetting resin is used, there is a possibility that the peel adhesion force (the chip peel force obtained by the below-described measurement method) at high temperatures decreases, and hence it is possible to properly use the thermosetting resin according to the intended purpose.

The first adhesive layer 21 and/or the second adhesive layer 22 may contain a filler. Examples of the filler include particles of gold, silver, copper, nickel, iron, aluminum, stainless steel, silicon oxide, silicon carbide, boron nitride, aluminum oxide, aluminum borate or aluminum nitride. Among these, when electric conductivity is required for the adhesive layer on the basis of the structure of semiconductor packages, it is preferable to use electrically conductive fillers such as gold, silver, copper, nickel, iron, aluminum and stainless steel. On the other hand, when electrical insulation is required for the adhesive layer, it is preferable to use electrical insulating fillers such as silicon oxide, silicon carbide, boron nitride, aluminum oxide, aluminum borate and aluminum nitride.

It is possible to properly use the fillers according to the intended functions. For example, the metal fillers are added for the purpose of imparting, to the adhesive composition, electrical conductivity, thermal conductivity, thixotropy and the like, the non-metal inorganic fillers are added for the purpose of imparting, to the adhesive film, thermal conductivity, low expansibility, low hygroscopicity and the like, and organic fillers are added for the purpose of imparting, to the adhesive film, toughness and the like. These metal fillers, inorganic fillers and organic fillers can be used each alone or in combinations of two or more thereof. Among others, the metal fillers, the inorganic fillers or the insulating fillers are preferable because these fillers can impart the properties required for semiconductor devices; among the inorganic fillers or the insulating fillers, boron nitride is more preferable because boron nitride is satisfactory in the dispersibility in resin varnish and effective in improving the adhesive strength.

The particle size of the filler is not particularly limited; however, usually, the average particle size is preferably 0.001 to 50 μm and more preferably 0.005 to 10 μm. The average particle size of the filler is preferably 10 μm or less and more preferably 5 μm or less. The maximum particle size of the filler is preferably 25 μm or less and more preferably 20 μm or less. The lower limits of the average particle size and the maximum particle size of the filler are not particularly limited; however, usually both of these lower limits are 0.1 μm. It is preferable for the filler to satisfy both of the average particle size of 10 μm or less and the maximum particle size of 25 μm or less. When the average particle size exceeds 10 μm and the maximum particle size exceeds 25 μm, the effect of the fracture toughness improvement tends to decrease. When a filler in which the maximum particle size is 25 μm or less and the average particle size exceeds 10 μm is used, the effect of the adhesive strength improvement tends to decrease. When a filler in which the average particle size is 10 μm or less and the maximum particle size exceeds 25 μm is used, the particle size distribution becomes broad, and variation tends to occur in the adhesive strength. Additionally, the surface of the adhesive layer becomes rough and the adhesion force tends to decrease.

Examples of the measurement methods of the average particle size and the maximum particle size of the filler include a method in which a scanning electron microscope (SEM) is used and the particle sizes of about 200 particles of the filler are measured. When a SEM is used, the particle size of the filler can be measured, for example, as follows: a semiconductor element and a semiconductor supporting substrate are adhered to each other by using a double-faced adhesive film, then curing by heating (preferably at 150 to 200° C. for 1 to 10 hours) is performed to prepare a sample, then the central portion of the sample is cut to obtain a cross section, and the cross section is observed with the SEM to measure the particle size. When the filler is a metal filler or an inorganic filler, also adoptable is a method in which the adhesive layer is heated in an oven set at 600° C. for 2 hours to decompose and volatilize the resin component, and the remaining filler is observed and measured with a SEM. When the filler itself is observed with a SEM, the double-faced adhesive tape is bonded onto the sample stage for SEM observation, and the filler is sprinkled on the adhesive surface and then deposited by ion sputtering.

The amount of the filler is determined according to the type of the filler and the properties or functions to be imparted. The amount of the filler is set at 1 to 8000 parts by mass in relation to 100 parts by mass of the polyimide resin. When the amount of the filler is less than 1 part by mass, the effects of imparting the properties or functions due to the addition of the filler are not obtained, and when the amount of the filler exceeds 8000 parts by mass, the adhesiveness decreases; either case is unpreferable. The mixing amount of the filler is not particularly limited; however, the mixing amount of the filler is preferably 3 to 70% by mass and more preferably 5 to 40% by mass in relation to the total mass of the adhesive layer. When this mixing amount is less than 3% by mass, the adhesive strength under high temperatures tends to decrease, and when this mixing amount exceeds 70% by mass, the roughness of the surface increases and the heat-pressure bonding property of the adhesive film tends to lower.

The first adhesive layer 21 and/or the second adhesive layer 22 may further contain a coupling agent. The coupling agent is not particularly limited, and examples of the coupling agent include: silane coupling agents such as methyltrimethoxysilane, methyltriethoxysilane, phenyltrimethoxysilane, phenyltriethoxysilane, vinyltrimethoxysilane, vinyltriethoxysilane, vinyltriacetoxysilane, vinyl-tris(2-methoxyethoxy)silane, γ-methacryloxypropyltrimethoxysilane, γ-methacryloxypropylmethyldimethoxysilane, methyltri(methacryloxyethoxy)silane, γ-acryloxypropyltrimethoxysilane, γ-aminopropyltrimethoxysilane, γ-aminopropyltriethoxysilane, N-β-(aminoethyl)-γ-aminopropyltrimethoxysilane, N-β-(aminoethyl)-γ-aminopropylmethyldimethoxysilane, N-β-(N-vinylbenzylaminoethyl)-γ-aminopropyltrimethoxysilane, γ-anilinopropyltrimethoxysilane, γ-ureidopropyltrimethoxysilane, γ-ureidopropyltriethoxysilane, 3-(4,5-dihydroimidazolyl)propyltriethoxysilane, β-(3,4-epoxycyclohexyl)ethyltrimethoxysilane, γ-glycidoxypropyltrimethoxysilane, γ-glycidoxypropylmethyldiethoxysilane, γ-glycidoxypropylmethyldiisopropenoxysilane, methyltriglycidoxysilane, γ-mercaptopropyltrimethoxysilane, γ-mercaptopropyltriethoxysilane, γ-mercaptopropylmethyldimethoxysilane, trimethylsilyl isocyanate, dimethylsilyl isocyanate, phenylsilyl triisocyanate, tetraisocyanate silane, methysilyl triisocyanate, vinylsilyl triisocyanate and ethoxysilane triisocyanate; and titanium coupling agents such as tetramethyl titanate, tetraethyl titanate, tetrapropyl titanate, tetraisopropyl titanate, tetrabutyl titanate, tetraisobutyl titanate, tetra 2-ethylhexyl titanate, tetrastearyl titanate, tetraoctylene glycol titanate, isopropyltriisostearoyl titanate, isopropyltrioctanoyl titanate, isopropyldimethacrylisostearoyl titanate, isopropyltridodecylbenzenesulfonyl titanate, isopropylisostearoyldiacryl titanate, isopropyltris(dioctyl phosphate) titanate, isopropyltricumylphenyl titanate, isopropyltris(dioctyl pyrophosphate) titanate, isopropyltri(N-aminoethyl.aminoethyl) titanate, tetraisopropylbis(dioctyl phosphite) titanate, tetraoctylbis(ditridecyl phosphite) titanate, tetra(2,2-diallyloxymethyl-1-butyl)bis(di-tridecyl) phosphite titanate, dicumylphenyloxyacetate titanate, bis(dioctyl pyrophosphate)oxyacetate titanate, diisostearoylethylene titanate, bis(dioctyl pyrophosphate)ethylene titanate, polyalkyl titanate, polyaryl titanate, polyacyl titanate and polyphosphate titanate.

The mixing amount of the coupling agent is preferably 0.1 to 10 parts by mass and more preferably 0.5 to 5 parts by mass in relation to the total mass of each of the adhesive layers. When this mixing amount is less than 0.1 part by mass, the improvement effect of the adhesive strength is poor, and when this mixing amount exceeds 10 parts by mass, the volatile component becomes large in amount and foaming in the heating steps tends to readily occur.

The adhesive layers 21 and 22 my each contain a felxibilizing material. As the felxibilizing material, various liquid rubbers and various thermoplastic resins are used; examples of the felxibilizing material include polybutadiene, maleinized polybutadiene, acrylized polybutadiene, methacrylized polybutadiene, epoxidized polybutadiene, acrylonitrile butadiene rubber, carboxy terminated acrylonitrile butadiene rubber, amino terminated acrylonitrile butadiene rubber, vinyl terminated acrylonitrile butadiene rubber, styrene butadiene rubber, polyvinyl acetate, polymethyl acrylate, c-caprolactone-modified polyester, phenoxy resin and polyimide.

The molecular weight of the felxibilizing material is usually such that the number average molecular weight is preferably 500 to 500000 and more preferably 1000 to 200000.

The mixing amount of the felxibilizing material is preferably 1 to 50 parts by mass and more preferably 5 to 30 parts by mass in relation to the total mass of each of the adhesive layers. When this mixing amount is less than 1 part by mass, the felxibilization effect tends to be small, and when this mixing amount exceeds 50 parts by mass, the tackiness increases, and the handleability and the processability of the adhesive film tend to decrease.

The adhesive layers 21 and 22 may contain one or more of additives: such as a moisture absorbent such as calcium oxide or magnesium oxide; a wettability improver such as a fluorochemical surfactant, a nonionic surfactant or a higher fatty acid; an antifoaming agent such as a silicone oil; an ion trapping agent such as an inorganic ion exchanger; and a flame retardant such as a bromine compound or a metal hydrate.

The thickness of each of the adhesive layers 21 and 22 is not particularly limited; however, the thickness of each of the adhesive layers is preferably 1 to 100 μm and more preferably 5 to 50 μm. When the thickness of the adhesive layer is less than 1 μm, it is difficult to maintain the thickness thereof uniform, and the adhesiveness also tends to decrease. On the other hand, when the thickness of the adhesive layer exceeds 100 μm, the deformation of the adhesive film itself, at the time of adhering a substrate and an element to each other or in a subsequent heating step, tends to become large.

The double-faced adhesive film 100 becomes higher in the elastic modulus in the vicinity of room temperature by using the supporting film 10 as the base substrate, as compared to an adhesive film composed of a single adhesive layer. Herewith, the processability of the film is improved and satisfactory workability is obtained.

It is preferable that the supporting film (base substrate) 10 is formed of a material small in property variation due to heating. Herewith, it is possible to more effectively suppress the heat shrinkage and the heat expansion of the double-faced adhesive film itself due to heating in the steps, after mounting the element on the substrate, such as a step of curing the adhesive film, a wire bonding step and a sealing step.

From such a viewpoint, the Tg of the supporting film 10 is preferably 100° C. or higher, more preferably 150° C. or higher and furthermore preferably 200° C. or higher. By using a supporting film having a high Tg, prevented is the deformation due to the application of a varnish and the heat drying of the varnish at the time of forming the adhesive layers 21 and 22. Also prevented is the plastic deformation of the adhesive layers at the time of being exposed to high temperatures after the adhesion. From the same viewpoint, the coefficient of linear expansion of the supporting film 10 is preferably 100 ppm or less and more preferably 50 ppm or less.

The material quality of the supporting film 10 is not particularly limited, and various polymer films, organic-inorganic composite materials, metals and the like can be used. For the purpose of achieving such properties as described above, it is preferable that the supporting film 10 is a film of a polymer selected from the group consisting of polyethylene terephthalate, polybutylene terephthalate, polyethylene naphthalate, polyimide, polyamide, polyamideimide, polyacetal, polycarbonate, polyethersulfone, polyphenylene sulfide, polyphenylene ether, polyetherketone, polyarylate, polyetheramide, polyetherimide, polyetheramideimide, wholly aromatic polyester and liquid crystal polymers; it is more preferable that the supporting film 10 is a film of a polymer selected from the group consisting of polyethylene terephthalate, polybutylene terephthalate, polyethylene naphthalate, polyimide, polyamide, polyamideimide, polyacetal, polycarbonate, polyethersulfone, polyphenylene sulfide, polyphenylene ether, polyetherketone, polyarylate and liquid crystal polymers; and it is furthermore preferable that the supporting film 10 is a film of a polymer selected from the group consisting of aromatic polyimide, aromatic polyamideimide, aromatic polyethersulfone, polyphenylene sulfide, aromatic polyetherketone, polyarylate, polyethylene naphthalate and liquid crystal polymers.

The supporting film 10 may also be a film having been subjected to plasma treatment or corona treatment of the surface thereof or a film having been subjected to chemical treatment with a coupling agent or the like, for the purpose of improving the adhesiveness to the adhesive layers 21 and 22.

The thickness of the supporting film 10 is not particularly limited; however, the thickness of the supporting film is preferably 5 to 200 μm, more preferably 5 to 150 μm, furthermore preferably 10 to 100 μm and particularly preferably 15 to 75 μm. When the thickness of the supporting film 10 becomes less than 5 μm, the handleability at the time of producing the adhesive film tends to decrease. When the thickness of the supporting film 10 exceeds 200 μm, the variation of the thickness of the supporting film itself tends to become large.

As the cover films, various films can be used without imposing particular restriction; however, preferable as the cover films are polyethylene terephthalate, polybutylene terephthalate, polyethylene naphthalate, polyethylene, polypropylene and polyolefin, or the multilayer films in which these polymers different in material quality are laminated; and for the respective cover films 31 and 32, the same film or different films can be used. Additionally, the cover films 31 and 32 may be the films in which the surface of the one side or the surfaces of both sides of each of the cover films 31 and 32 have been subjected to plasma treatment or corona treatment, or chemical treatment with a coupling agent or a release treatment agent, in consideration of the adhesiveness to and the releasability from the adhesive layers 21 and 22. For the respective cover films 31 and 32, films different in colors can be used for the purpose of making the adhesive layers 21 and 22 distinguishable from each other at a glance. The coloring method is not particularly limited; however, examples of the coloring method include a method in which pigments are added to the materials themselves for the cover films and a method in which the cover films are formed as multilayer films including pigment layers.

The thickness of each of the cover films is not particularly limited, and various films can be used; however, films of 5 to 150 μm in thickness are preferable and films of 10 to 100 μm in thickness are more preferable. Additionally, for the respective cover films 31 and 32, films being equal in thickness or films different in thickness can be used. When the thickness of the cover films is thinner than 5 μm, the cover film tends to break and the handleability at the time of releasing the cover film becomes insufficient, and when the thickness is thicker than 150 μm, the cover film tends to break, burrs, scraps or the like tend to occur at the time of applying the hole drilling processing or the like to the cover film.

The Tgs, after curing, of the adhesive layers 21 and 22 and the supporting film 10 are measured preferably by TMA (Thermo Mechanical Analysis) or DMA (Dynamic Mechanical Analysis).

The coefficient of linear expansion of the supporting film 10 is measured preferably by TMA (Thermo Mechanical Analysis).

It is possible to obtain the double-faced adhesive film 100, for example, by the method including a step of forming the first adhesive layer 21 on the one surface of the supporting film 10, a step of forming the second adhesive layer 22 on the other surface of the supporting film 10, and a step of bonding the cover films 31 and 32 respectively on the surfaces, opposite to the supporting film 10, of the first adhesive layer and the second adhesive layer.

It is possible to obtain the double-faced adhesive film 100, for example, by the method including a step of forming the first adhesive layer 21 by directly applying a varnish to the one surface of the supporting film 10 and by drying the applied varnish, a step of forming the second adhesive layer 22 by applying a varnish to the other surface of the supporting film 10 and by drying the applied varnish, and a step of bonding the cover films 31 and 32 respectively on the first and second adhesive layers 21 and 22. It is preferable to sequentially form the first adhesive layer 21 and the second adhesive layer 22.

The varnish includes, for example, an adhesive containing such components (a polyimide resin, a thermosetting resin, a filler and the like) as described above, constituting the adhesive layers 21 and 22 and a solvent in which these components are dissolved or dispersed. The method for applying the varnish to the supporting film is not particularly limited; however, the varnish application method is selected, for example, from roll coating, reverse roll coating, gravure coating, bar coating and die coating.

The varnish applied to the supporting film 10 is dried until the solvent content comes to be 0.5 to 10% by mass. The drying is usually performed by heating.

According to the double-faced adhesive film obtained by the method including the step of directly applying the varnish to the both surfaces of the supporting film as described above, the shrinkage and the expansion of the adhesive film in mounting the element and subsequent heating steps are suppressed.

For the purpose of maintaining high the connection reliability of semiconductor elements and the like by alleviating the thermal stress, in general it is advantageous that the elastic modulus of the adhesive film is low. However, an adhesive film having a low elastic modulus is insufficient in the rigidity at room temperature, and hence there occurs a problem with respect to the processability of the adhesive film as the case may be. For example, there has been a problem that when a processing such as hole drilling or punching is applied to the adhesive film, the adhesive layers flow and hence no processing can be performed, or whiskers or burrs occur. However, owing to the double-faced adhesive film according to the present embodiment, even when the rigidity of the adhesive layers is low, the decrease of the processability is prevented. Therefore, by using the double-faced adhesive film according to the present embodiment, the production of electronic component modules such as high reliability semiconductor packages is facilitated.

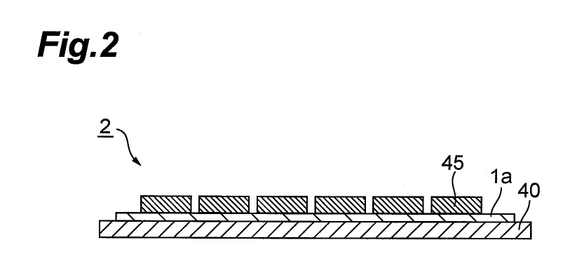

FIG. 2 is a cross sectional view illustrating an embodiment of the electronic component module. The electronic component module 2 shown in FIG. 2 includes a substrate 40, a plurality of elements 45, which are selected from semiconductor elements and MEMS elements, mounted on the substrate 40, and a adhesive layer 1a intervening between the substrate 40 and the elements 45. The adhesive layer 1a is formed of the double-faced adhesive film 100 in which the cover films 31 and 32 have been removed. In other words, the adhesive layer 1a is formed of the supporting film 10, and the two cured adhesive layers 21 and 22 respectively disposed on the both surfaces of the supporting film 10.

The electronic component module according to the present invention is not limited to the above-described embodiment, and it is possible to optionally modify the electronic component module as long as such a modification does not deviate from the gist of the present invention. For example, the electronic component module according to the present invention may be a semiconductor package including a plurality of semiconductor elements, a MEMS module including MEMS elements or a module including both semiconductor elements and MEMS elements.

It is possible to produce the electronic component module 2, for example, by the method including, in the order of description, a step of removing the cover film 32 from the double-faced adhesive film 100 and thermally pressure bonding the second adhesive layer 22 to one adherend (the substrate 40 or the elements 45), and a step of removing the cover film 31 from the double-faced adhesive film 100 and thermally pressure bonding the first adhesive layer 21 to the other adherend (the substrate 40 or the elements 45).

The temperature at the time of thermally pressure bonding the adhesive layer falls preferably within a range equal to or lower than a temperature that is higher by 140° C., more preferably within a range equal to or lower than a temperature that is higher preferably by 100° C., and furthermore preferably within a range equal to or lower than a temperature that is higher by 80° C., than the Tg, after curing, of the adhesive layer to be thermally bonded. When this temperature exceeds the temperature higher by 140° C. than the Tg of the adhesive layer to be thermally bonded, the deformation suppression effect of the first adhesive layer at the time of mounting the elements tends to be small, the suppression effect being obtained by the condition that the Tg, after curing, of the first adhesive layer is higher than the Tg, after curing, of the second adhesive layer. Additionally, the effect of suppressing the warpage due to the differences between the coefficient of linear expansion of the substrate and the coefficients of linear expansion of the elements tends to be small.

The pressure at the time of the thermal pressure bonding is not particularly limited; however, this pressure is preferably 0.02 to 20 MPa. When this pressure is less than 0.02 MPa, the adhesive strength tends to decrease, and when this pressure exceeds 20 MPa, the deformation of the adhesive film tends to be large.

When the double-faced adhesive film is thermally pressure bonded to the substrate or the elements, for the purpose of suppressing the formation of air bubbles in the adhesive layers due to the volatilization, at the time of heat-pressure bonding, of the hygroscopic moisture of the substrate and/or the double-faced adhesive film, it is possible to beforehand dry, where necessary, the substrate and/or the double-faced adhesive film.

It is possible to adopt: a method in which a single double-faced adhesive film is thermally pressure bonded to a substrate, and then a plurality of elements are thermally pressure bonded to the thermally pressure bonded double-faced adhesive film; a method in which a plurality of double-faced adhesive films are respectively thermally pressure bonded to a substrate, and then elements are thermally pressure bonded to the respective double-faced adhesive films; or a method in which double-faced adhesive films are beforehand thermally pressure bonded to respective elements, and then the double-faced adhesive films thermally pressure bonded to the elements are thermally pressure bonded to the substrate. For the purpose of contracting the production process, preferable is the method in which a double-faced adhesive film is thermally pressure bonded to the predetermined portion of the substrate, and then a plurality of elements are thermally pressured bonded to the thermally pressure bonded double-faced adhesive film.

After the double-faced adhesive film is thermally pressure bonded to the substrate and the elements, where necessary, the first and second adhesive layers may be cured by heating. The temperature applied in this case is not particularly limited; however, the concerned temperature is preferably 200° C. or lower, more preferably 180° C. or lower and furthermore preferably 160° C. or lower. When the temperature of the step of curing the adhesive film exceeds 200° C., the thermal expansion/shrinkage of the adhesive film itself, or the deformation of the adhesive film itself due to the volatilization of the volatile component or the hygroscopic moisture contained in the adhesive film tends to be large.

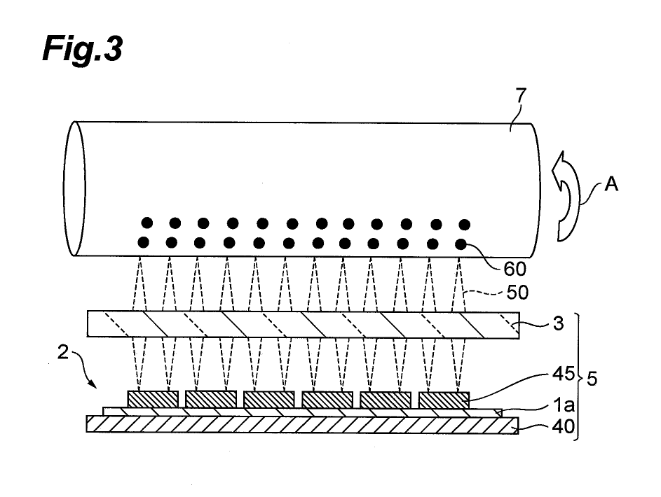

When the elements 45 are LED chips, the electronic component module 2 can constitute an LED printer head. FIG. 3 is a schematic view illustrating an embodiment of exposure with an LED printer head. In the embodiment illustrated in FIG. 3, a photosensitive drum 7 is exposed in a predetermined pattern with an LED printer head 5.

The LED printer head 5 includes the electronic component module 2 and a lens 3 disposed on the side facing the elements (LED chips) 45 of the electronic component module 2. The LED printer head 5 is disposed in a manner facing the photosensitive drum 7 rotating in the direction of an arrow A. Light 50 emitted from the LED chips 45 is focused with the lens 3 at predetermined positions 60 on the photosensitive drum 7. Herewith, the predetermined positions 60 on the photosensitive drum 7 are exposed.

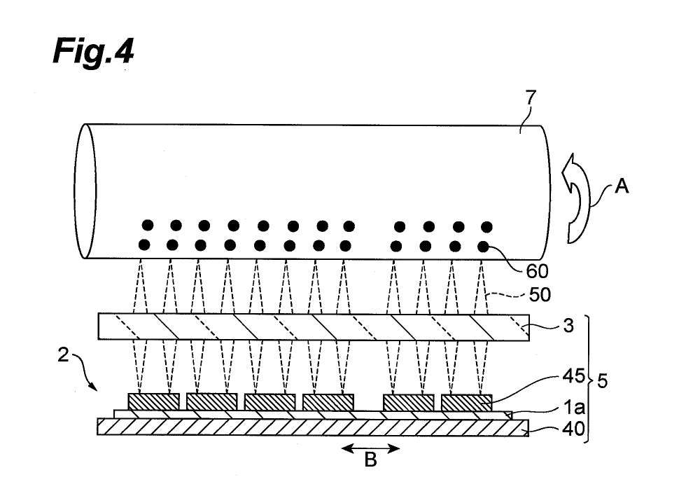

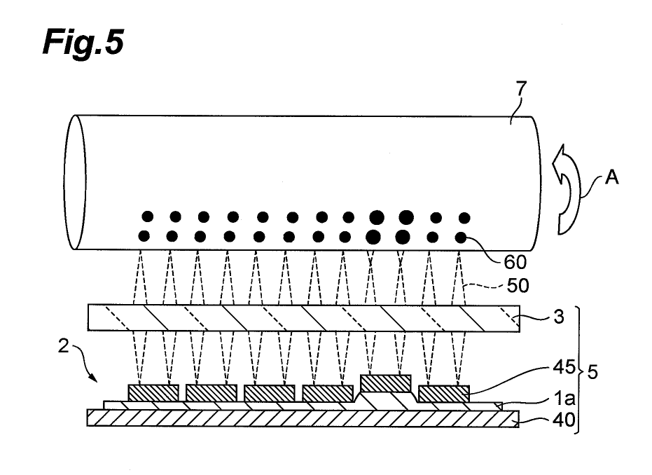

For the purpose of exposing the intended positions on the photosensitive drum 7 with a high precision, it is necessary that the positions and the heights of the plurality of the LED chips 45 be accurately controlled. For example, as shown in FIG. 4, when the adhesive layer 1a deforms and hence the mutual interval of the adjacent LED chips 45 widens in the direction of an arrow B, an unexposed portion occurs on the surface of the photosensitive drum 7, and thus leads to the occurrence of an unprinted portion. Conversely, when the mutual intervals of the LED chips shorten, excessively exposed portions occur and thus the printing becomes blurred. Additionally, as shown in FIG. 5, when the heights of the LED chips 45 vary, defocusing occurs and thus excessively exposed portions and insufficiently exposed portions may occur. This also causes the printing to become blurred.

By mounting the elements (LED chips) 45 on the substrate 40 by use of the double-faced adhesive film according to the present embodiment, it is possible to effectively prevent the printing failures due to such deformations as described above.

### Examples

Hereinafter, the present invention is more specifically described with reference to Examples. However, the present invention is not limited to following Examples.

<Preparation of Varnishes for Forming Adhesive Layers>

(Varnish 1)

In a 500-ml four-neck flask equipped with a thermometer, a stirrer and a calcium chloride tube, 1,3-bis(3-aminopropyl)tetramethyldisiloxane (0.03 mol) and 1,12-diaminododecane (0.08 mol) as diamines and 150 g of N-methyl-2-pyrrolidone (NMP) as a solvent were placed and stirred at 60° C.

After dissolution of the diamines, 1,10-(decamethylene)bis(trimellitate dianhydride) (0.02 mol) and 4,4′-(4,4′-isopropylidenediphenoxy)bis(phthalic acid dianhydride) (0.08 mol) were added little by little, and were allowed to react at 60° C. for 3 hours.

Then, while blowing N₂ gas through the reaction solution, the reaction solution was heated to 170° C., the water in the reaction system was removed azeotropically together with part of the solvent over 3 hours, and thus an NMP solution of a polyimide resin was obtained.

Per 100 parts by mass (as the solid content in the NMP solution) of the polyimide resin obtained as described above, 6 parts by mass of a cresol novolac type epoxy resin (trade name: YDCN-702, manufactured by Tohto Kasei Co., Ltd.), 3 parts by mass of 4,4′-(1-4-(1-(4-hydroxyphenyl)-1-methylethyl)phenyl)ethylidene)bisphenol (trade name: Tris-P-PA, manufactured by Honshu Chemical Industry Co., Ltd.), 0.5 part by mass of tetraphenylphosphonium tetraphenylborate (trade name: TPPK, manufactured by Tokyo Chemical Industry Co., Ltd.) and 10 parts by mass of a boron nitride filler (trade name: HP-P1, manufactured by Mizushima Ferroalloy Co., Ltd.) were added to the solution, and the resulting mixture was sufficiently kneaded and thus the varnish 1 was obtained.

(Varnish 2)

In a 500-ml four-neck flask equipped with a thermometer, a stirrer and a calcium chloride tube, 1,3-bis(3-aminopropyl)tetramethyldisiloxane (0.07 mol) and 4,9-dioxadecane-1,12-diamine (0.03 mol) as diamines and 150 g of NMP were placed and stirred at 60° C.

After dissolution of the diamines, 1,10-(decamethylene)bis(trimellitate dianhydride) (0.03 mol) and 4,4′-oxydiphthalic acid dianhydride (0.07 mol) were added little by little, and were allowed to react at 60° C. for 3 hours.

Then, while blowing N₂ gas through the reaction solution, the reaction solution was heated to 170° C., the water in the reaction system was removed azeotropically together with part of the solvent over 3 hours, and thus an NMP solution of a polyimide resin was obtained.

Per 100 parts by mass (as the solid content in the NMP solution) of the polyimide resin obtained as described above, 6 parts by mass of a cresol novolac type epoxy resin (trade name: YDCN-702, manufactured by Tohto Kasei Co., Ltd.), 2 parts by mass of 4,4′-(1-4-(1-(4-hydroxyphenyl)-1-methylethyl)phenyl)ethylidene)bisphenol (trade name: Tris-P-PA, manufactured by Honshu Chemical Industry Co., Ltd.) and 0.5 part by mass of tetraphenylphosphonium tetraphenylborate (trade name: TPPK, manufactured by Tokyo Chemical Industry Co., Ltd.) were added to the solution, and the boron nitride filler (manufactured by Mizushima Ferroalloy Co., Ltd.) in an amount of 12% by mass in relation to the total solid content and Aerosol (silica) filler (trade name: R972, manufactured by Japan Aerosil Co., Ltd.) in an amount of 2% by mass in relation to the total solid content were added to the solution, and the resulting mixture was sufficiently kneaded and thus the varnish 2 was obtained.

(Varnish 3)

In a nitrogen atmosphere, in a four-neck flask equipped with a stirrer and a calcium chloride tube, an ortho-cresol/novolac type epoxy resin (13.2% by mass, trade name: YDCN703, manufactured by Tohto Kasei Co., Ltd.), a xylene-modified phenolic resin (11.1% by mass, trade name: XLC-LL, manufactured by Mitsui Chemicals Inc.), a fine silica filler (7.8% by mass, trade name: R972V, manufactured by Japan Aerosil Co., Ltd.), a mercapton coupling agent (0.4% by mass, trade name: A189, manufactured by Nippon Unicar Co., Ltd.), a ureidosilane coupling agent (0.8% by mass, trade name: A-1160, manufactured by Nippon Unicar Co., Ltd.), 1-cyanoethyl-2-phenhylimidazole (0.025% by mass, trade name: 2PZ-CN, manufactured by Shikoku Chemicals Corp.) and an epoxy-containing acrylic rubber (66.6% by mass, trade name: HTR-860P-3, manufactured by Teikoku Chemical Industry Co., Ltd.) were placed, and the resulting mixture was sufficiently kneaded and thus the varnish 3 was obtained.

(Varnish 4)

In a nitrogen atmosphere, in a 500-ml four-neck flask equipped with a thermometer, a stirrer and a calcium chloride tube, 258.3 g (0.63 ml) of 2,2-bis[4-(4-aminophenoxy)phenyl]propane and 10.4 g (0.042 mol) of 1,3-bis(3-aminopropyl)tetramethyldisiloxane were placed and dissolved in 1450 g of NMP.

The resulting solution was cooled to 0° C., and 180.4 g (0.857 mol) of trimellitic acid anhydride chloride was further added to the solution. After trimellitic acid anhydride chloride was dissolved, 130 g of trimethylamine was added. The solution was continuously stirred at room temperature for 2 hours, then increased in temperature to 180° C., and allowed to react for 5 hours to complete the imidization.

The obtained reaction solution was poured in methanol to precipitate a polymer. The polymer was dried, then dissolved in NMP, the resulting NMP solution was poured in methanol to again precipitate the polymer. The precipitated polymer was dried under reduced pressure, and thus a polyetheramideimide powder was obtained. In NMP, 120 g of the obtained polyetheramideimide powder and 6 g of a silane coupling agent (trade name: SH6040, manufactured by Dow Corning Toray Co., Ltd.) were dissolved, and thus the varnish 4 of an aromatic polyetheramideimide was obtained.

<Glass Transition Temperature of Adhesive Layer>

Each of the varnishes 1 to 4 was applied to a polyethylene terephthalate film having undergone a release treatment, heated at 80° C. for 30 minutes, successively heated at 150° C. for 30 minutes, then the polyethylene terephthalate film was released at room temperature (25° C.), and thus a 25 μm thick adhesive layer was obtained.

The obtained adhesive layers were cured by heating at 180° C. for 1 hour, and 4×20 mm sized samples were cut out therefrom. For each of these samples, the displacement magnitude of the sample was measured, by using the TMA 120 manufactured by Seico Electronics Industrial Co., Ltd., under the following conditions: Extension; the temperature increase rate: 5° C./min; and the length of the measurement sample: 10 mm, and a curve representing the relation between the displacement magnitude and the temperature was obtained. From the thus obtained curves of the samples, the glass transition temperature (Tg) was obtained for each of the samples. The results thus obtained are shown in Table 1.

TABLE 1

| | | | | |
|---|---|---|---|---|
| Varnish for forming | 1 | 2 | 3 | 4 |
| adhesive layer | | | | |
| Glass transition temperature | 71 | 52 | 25 | 210 |
| (Tg) (unit: ° C.) | | | | |

<Preparation of Double-Faced Adhesive Films>

(Double-Faced Adhesive Film 1)

A 50 μm thick polyimide film (Upilex SGA manufactured by Ube Industries, Inc., coefficient of linear expansion: 30 ppm) was prepared, and this was used as the “supporting film 1.” To one surface of the supporting film 1, the varnish 2 was applied, and heated at 80° C. for 30 minutes and successively at 150° C. for 30 minutes, and thus a 25-μm thick second adhesive layer was formed on one surface of the supporting film 1.

Next, the varnish 1 was applied to the surface of the supporting film 1, opposite to the second adhesive layer, heated at 80° C. for 30 minutes and successively at 150° C. for 30 minutes, and thus a 25-μm thick first adhesive layer was formed. Thus, a double-faced adhesive film 1 was obtained.

(Double-Faced Adhesive Film 2)

A three-layer-structured double-faced adhesive film 2 was obtained through the same steps as for the double-faced adhesive film 1 except that the second adhesive layer was formed by using the varnish 3.

(Double-Faced Adhesive Film 3)

A three-layer-structured double-faced adhesive film 3 was obtained through the same steps as for the double-faced adhesive film 1 except that a 50-μm thick polyethylene naphthalate film (manufactured by Teijin DuPont Films Ltd.) was uses as a “supporting film 2” in place of the supporting film 1.

(Double-Faced Adhesive Film 4)

The varnish 1 was applied to a polyethylene terephthalate film having undergone a release treatment, heated at 80° C. for 30 minutes and successively at 150° C. for 30 minutes, and thus a 50-μm thick adhesive layer was formed. In the same manner, by using the varnish 2, a 50-μm thick adhesive layer was formed on a polyethylene terephthalate film. Next, these two adhesive layers were bonded to each other under the conditions of 80° C., 10 N/cm and 2 m/min, the outer polyethylene terephthalate films were peeled off, and thus a 100-μm thick double-faced adhesive film 4 was obtained.

(Double-Faced Adhesive Film 5)

A three-layer-structured double-faced adhesive film 5 was obtained through the same steps as for the double-faced adhesive film 1 except that both of the first adhesive layer and the second adhesive layer were formed by using the varnish 1.

(Double-Faced Adhesive Film 6)

A three-layer-structured double-faced adhesive film 6 was obtained through the same steps as for the double-faced adhesive film 1 except that the first adhesive layer was formed by using the varnish 4 and the second adhesive layer was formed by using the varnish 1.

(Double-Faced Adhesive Film 7)

A five-layer-structured double-faced adhesive film 7 was obtained through the same steps as for the double-faced adhesive film 1 except that a 50-μm thick polypropylene film (Torayfan manufactured by Toray Industries, Inc., coefficient of linear expansion: 115 ppm) was used as a “supporting film 3” in place of the supporting film 1.

<Coefficients of Linear Expansion of Supporting Films>

From the supporting films 1 to 3, 4×20 mm sized samples were cut out. For each of these samples, the displacement magnitude of the sample was measured, by using the TMA 120 manufactured by Seico Electronics Industrial Co., Ltd., under the following conditions: Extension; the temperature increase rate: 5° C./min; and the length of the measurement sample: 10 mm, and thus the coefficient of linear expansion was obtained. The coefficients of linear expansion of the respective supporting films are shown in Table 2.

TABLE 2

| | | | |
|---|---|---|---|
| Supporting film | 1 | 2 | 3 |
| Coefficient of linear expansion | 28 | 22 | 115 |
| (unit: ppm) | | | |

<Evaluation of Double-Faced Adhesive Films>

(Thermal Shrinkage Factor)

From each of the double-faced adhesive films 1 to 7, a 80 mm×80 mm sized specimen was cut out. A mark point was put at the center of each side of the cut-out specimens, and the lengths between the opposite mark points were measured to the unit of 0.001 mm.

Next, the specimens were heated for 1 hour in a furnace maintained at 180° C. under a condition allowing free shrinkage. The lengths between the same mark points of the specimens after heating as the points of the specimens before heating were measured to the unit of 0.001 mm. The ratios of the differences, between before and after heating, of the lengths between the mark points to the lengths between the mark points before heating were taken as the thermal shrinkage factors (%).

(Chip Warpage)

From each of the double-faced adhesive films 1 to 7, a 12 mm×12 mm sized specimen was accurately cut out. Each of the cut-out specimens was heat-pressure bonded to a copper lead frame with silver plating in such a way that the second adhesive layer faced the copper lead frame. The heat-pressure bonding was performed by using a heat-pressure bonding tester manufactured by Nikka Setsubi Engineering Co., Ltd. under the following conditions:

Temperature of a hot plate: The glass transition temperature of the second adhesive layer +60° C. (for example, when the second adhesive layer was formed with the varnish 2, the temperature of the hot plate was 112° C. (=52° C.+60° C.)).

Pressure bonding conditions: 10 N×10 sec

Next, a 100-μm silicon wafer was cut out to 10×10 mm. The cut-out silicon wafer was placed on the first adhesive layer, and the silicon chip was heat-pressure bonded to the copper lead frame by using the heat-pressure bonding tester (manufactured by Nikka Setsubi Engineering Co., Ltd.) under the following conditions:

Temperature of a hot plate: The glass transition temperature of the first adhesive layer +60° C. (for example, when the first adhesive layer was formed with the varnish 1, the temperature of the hot plate was 131° C. (=71° C.+60° C.)).

Pressure bonding conditions: 10 N×10 sec

Subsequently, the laminate composed of the silicon chip, the adhesive film and the copper lead frame with silver plating was heated for 1 hour in a furnace maintained at 180° C., and the silicon chip warpage (μm) which occurred after being allowed to stand to cool was measured by using a non-contact roughness gauge (manufactured by Keyence Corp.) on the basis of the method in which the scanning was performed over 12 mm on the diagonal line of the silicon chip.

(Maximum Protrusion Magnitude)

The second adhesive layers of the double-faced adhesive films 1 to 7 were completely wiped off by using cloth wetted with acetone, and thus two-layer-structured films, each composed of the supporting film and the first adhesive layer, were obtained. Each of the two-layer-structured films was accurately cut to a 10 mm×10 mm size, sandwiched between two slide glasses (76 mm×26 mm×1.0 to 1.2 mmt, manufactured by Matsunami Glass Ind., Ltd.), and was heat-pressure bonded by using a thermal pressure bonding tester manufactured by Tester Sangyo Co., Ltd., on a hot plate under the conditions of 10 MPa and 20 seconds. The temperature of the hot plate in this case was the glass transition temperature of the second adhesive layer +60° C. (for example, when the second adhesive layer was formed with the varnish 2, the temperature of the hot plate was 112° C. (=52° C.+60° C.)). Subsequently, by using a metallurgical microscope and an image analyzer manufactured by Olympus Corp., the maximum protrusion magnitude (μm) of the adhesive layer from the above-described 10 mm×10 mm sized supporting film was measured. As for the double-faced adhesive film 4, because it was impossible to wipe off only the second adhesive layer with acetone, used was a 50-μm thick adhesive film obtained by applying the vanish 1 to a polyethylene terephthalate film having undergone a release treatment and by drying the applied vanish. In this case, measured was the maximum protrusion magnitude (μm) of the adhesive layer from the 10 mm×10 mm sized polyethylene terephthalate film in place of the supporting film.

(Film Thickness Variation)

From each of the double-faced adhesive films 1 to 7, a 10 mm×10 mm sized specimen was accurately cut out. The thickness of each of the specimens was measured with a dial gauge at five points, and the average value of the measured values was defined as H₀. Subsequently, each of the specimen was sandwiched between Teflon sheets, and thermally pressed by using a thermal pressure bonding tester manufactured by Tester Sangyo Co., Ltd. on a hot plate under the conditions of 1 MPa and 20 seconds. The temperature of the hot plate in this case was set at the glass transition temperature of the first adhesive layer +60° C. (for example, when the first adhesive layer was formed with the varnish 1, the temperature of the hot plate was 131° C. (=71° C.+60° C.)). The thickness of each of the double-faced adhesive films after thermal pressing was measured at five points with the dial gauge and the average value of the measured values was defined as H₁. On the basis of the following formula, the film thickness variation was calculated.

Film thickness variation(μm)=H₁−H₀

(Surface Roughness (Ra))

From each of the double-faced adhesive films 1 to 7, a 10 mm×10 mm sized specimen was accurately cut out. The second adhesive layer side of each of the specimens was brought into contact with a slide glass (76 mm×26 mm×1.0 to 1.2 mmt, manufactured by Matsunami Glass Ind., Ltd.), and thermally pressed in this condition by using a thermal pressure bonding tester manufactured by Tester Sangyo Co. Ltd. under the conditions of 1 MPa and 20 seconds. The temperature of the hot plate in this case was set at the glass transition temperature of the second adhesive layer +60° C. (for example, when the second adhesive layer was formed with the varnish 2, the temperature of the hot plate was set at 112° C. (=52° C.+60° C.)). The arithmetic average roughness (Ra) of the surface of the second adhesive layer after the thermal pressing was measured by using a non-contact roughness gauge (manufactured by Keyence Corp.) by scanning over 10 mm.

(Voids)

From each of the double-faced adhesive films 1 to 7, a 10 mm×10 mm sized specimen was accurately cut out. Each of the specimens was sandwiched between two slide glasses (76 mm×26 mm×1.0 to 1.2 mmt, manufactured by Matsunami Glass Ind. Ltd.), and was thermally pressed by using a thermal pressure bonding tester manufactured by Tester Sangyo Co., Ltd. on a hot plate under the conditions of 1 MPa and 20 seconds. The temperature of the hot plate in this case was set at the glass transition temperature of the first adhesive layer +60° C. (for example, when the first adhesive layer was formed with the varnish 1, the temperature of the hot plate was 131° C. (=71° C.+60° C.)). After the thermal pressing, for each of the first adhesive layer and the second adhesive layer, the occurrence or nonoccurrence of voids in the adhesive layer was identified with an optical microscope.

(Peel Strength)

From each of the double-faced adhesive films 1 to 7, a 6 mm×6 mm sized specimen was accurately cut out. Each of the specimens was heat-pressure bonded to a 42-alloy lead frame in such a way that the second adhesive layer of the specimen faced the lead frame. The heat-pressure bonding was performed by using a heat-pressure bonding tester (manufactured by Nikka Setsubi Engineering Co., Ltd.) under the following conditions:

Temperature of a hot plate: The glass transition temperature of the second adhesive layer +60° C. (for example, when the second adhesive layer was formed with the varnish 2, the temperature of the hot plate was 112° C. (=52° C.+60° C.)).

Pressure bonding conditions: 10 N×10 sec

A 400-μm silicon wafer was rabbeted from the backside thereof to a depth of 250 μm, and then by breaking the wafer by applying force to the wafer from the front side thereof, a 5×5 mm sized fragmented silicon chip having a 150-μm thick protrusion in the edge portion of the front side of the wafer was prepared. The silicon chip was placed on the first adhesive layer, and the silicon chip was heat-pressure bonded to the lead frame by using the heat-pressure bonding tester (manufactured by Nikka Setsubi Engineering Co., Ltd.) under the following conditions:

Temperature of a hot plate: The glass transition temperature of the first adhesive layer +60° C. (for example, when the first adhesive layer was formed with the varnish 1, the temperature of the hot plate was 131° C. (=71° C.+60° C.)).

Pressure bonding conditions: 10 N×10 sec

The laminate composed of the silicon chip, the adhesive film and the 42-alloy lead frame, obtained by heat-pressure bonding, was heated for 1 hour in a furnace maintained at 180° C. Subsequently, the peel strength of the chip in the case where the laminate was heated on a hot plate at 260° C. for 20 seconds was measured.

The above-described evaluation results are shown in Table 3.

TABLE 3

| Double-faced adhesive film | | 1 | 2 | 3 | 4 | 5 | 6 | 7 |
|---|---|---|---|---|---|---|---|---|
| Supporting | Type | 1 | 1 | 2 | Absent | 1 | 1 | 3 |
| film | Coefficient of | 28 | 28 | 22 | — | 28 | 28 | 115 |
| | linear expansion | | | | | | | |
| | (ppm) | | | | | | | |
| | Thickness (μm) | 50 | 50 | 50 | — | 50 | 50 | 50 |
| Fist | Varnish | 1 | 1 | 1 | 1 | 1 | 4 | 1 |
| adhesive | Tg (° C.) | 71 | 71 | 71 | 71 | 71 | 210 | 71 |
| layer | Thickness (μm) | 25 | 25 | 25 | 50 | 25 | 25 | 25 |
| Second | Varnish | 2 | 3 | 2 | 2 | 1 | 1 | 2 |
| adhesive | Tg (° C.) | 52 | 25 | 52 | 52 | 71 | 71 | 52 |
| layer | Thickness (μm) | 25 | 25 | 25 | 50 | 25 | 25 | 25 |

| | | | | | | | |
|---|---|---|---|---|---|---|---|
| Thermal shrinkage factor (%) | <0.3 | <0.3 | <0.3 | 17 | <0.3 | <0.3 | 1.5 |
| Chip warpage (μm) | 65 | 75 | 60 | 50 | 80 | 250 | 70 |
| Maximum protrusion magnitude (μm) | 60 | 10 | 55 | 350 | 150 | <5 | 70 |
| Film thickness variation (μm) | 1 | 1 | 1 | −3 | 1 | 5 | 1 |
| Surface roughness Ra (μm) | 0.2 | 0.1 | 0.2 | 0.2 | 0.7 | 0.1 | 0.2 |
| Voids | Absent | Absent | Absent | Absent | Absent | Present | Absent |
| Peel strength (MPa) | 4.7 | 4.1 | 4.5 | 5.3 | 4.0 | 2.1 | 4.2 |

As shown in Table 3, the double-faced adhesive film 4 is such that the total thickness of the adhesive film is 100 μm as the thicknesses of the double-faced adhesive films 1 to 3 are, but the double-faced adhesive film 4 does not include any supporting film, and hence the thermal shrinkage factor is as large as 17%, the maximum protrusion magnitude is also large and the film thickness variation is also large. Because of these facts, there is a possibility that the positional deviation of elements at the time of mounting the elements on a substrate occurs and the positional deviation of the elements in the step of heating the adhesive film after mounting the elements on the substrate occurs.

The double-faced adhesive film 5 is such that the Tg difference between the two adhesive layers is absent, and hence the maximum protrusion magnitude of the first adhesive layer at the adhesion temperature of the second adhesive layer, that is, the deformation magnitude is large, and the surface roughness of the first adhesive layer is also large. Because of these facts, there is a possibility that the adhesive layers tends to flow at the time of mounting elements, and hence the positional deviation tends to occur, and additionally no stable adhesive strength is obtained after mounting the elements because the surface of the adhesive layers becomes roughened.

The double-faced adhesive film 6 is such that although the difference between the Tgs of the two adhesive layers is 10° C. or more, the Tg of the first adhesive layer exceeds 100° C., and hence it is necessary to pressure bond the double-faced adhesive film 6 at a high temperature equal to or higher than 200° C. Consequently, the chip warpage is large, and due to the fact that the second adhesive layer is exposed to high temperatures, voids occur and the thickness variation of the adhesive layers is large. Because of these facts, there is a possibility that the positional deviation of elements occur due to the chip warpage. Further, there is a possibility that due to the thickness variation caused by the voids, the variation of the mounting heights of the elements becomes large.

The double-faced adhesive film 7 is such that because the coefficient of linear expansion of the supporting film is 100 ppm or more, the thermal shrinkage factor is as large as 1.5%. Because of this fact, there is a possibility that the positional deviation of elements in the step of heating the adhesive film after mounting the elements on a substrate occurs.

On the other hand, according to the double-faced adhesive films 1 to 3, the effect of the differences between the coefficients of linear expansion of elements was suppressed, and as a result, it was possible to suppress the warpage. The deformation of the double-faced adhesive film due to the heat at the time of pressure bonding was also suppressed. Further, it was also possible to suppress the shrinkage and the expansion of the adhesive films itself in the step of heating the adhesive film after mounting the elements on the substrate. Additionally, from the values of the peel strength, it has also been verified that the double-faced adhesive films 1 to 3 each have the adhesive strength necessary for the case where these double-faced adhesive films are used for use in semiconductor packages or for use in MEMS modules.

<Preparation of Double-Faced Adhesive Films>

(Double-Faced Adhesive Film 5)

In the same manner as described above, a double-faced adhesive film 5 was obtained. Specifically, the supporting film 1 was used as the supporting film, the vanish 1 was applied to one surface of the supporting film, and heated at 80° C. for 30 minutes and successively at 150° C. for 30 minutes, and thus the 25-μm thick first adhesive layer was formed on one surface of the supporting film.

Next, the vanish 1 was applied to the surface of the supporting film, opposite to the first adhesive layer, and heated at 80° C. for 30 minutes and successively at 150° C. for 30 minutes, thus the 25-μm thick second adhesive layer was formed, and thus the three-layer-structured double-faced adhesive film 5 was obtained.

(Double-Faced Adhesive Film 8)

A three-layer-structured double-faced adhesive film 8 was obtained through the same steps as for the double-faced adhesive film 5 except that both of the first adhesive layer and the second adhesive layer were formed by using the varnish 2.

(Double-Faced Adhesive Film 9)

A three-layer-structured double-faced adhesive film 9 was obtained through the same steps as for the double-faced adhesive film 5 except that both of the first adhesive layer and the second adhesive layer were formed by using the varnish 3.

(Double-Faced Adhesive Film 10)

The varnish 1 was applied to a PET film (Purex A31, manufactured by Teijin DuPont Films Ltd.) having undergone a release treatment, and heated at 80° C. for 30 minutes and successively at 150° C. for 30 minutes, and thus a first adhesive layer was formed on the PET film. The first adhesive layer was transferred on the both surfaces of a 50-μm polyimide film (Upilex SGA manufactured by Ube Industries, Inc., coefficient of linear expansion: 30 ppm) by thermal lamination at 140° C., and thus the three-layer-structured double-faced adhesive film 10 was obtained.

(Double-Faced Adhesive Film 11)

A three-layer-structured double-faced adhesive film 11 was obtained in the same manner as for the double-faced adhesive film 10 except that the varnish 2 was used in place of the varnish 1.

<Measurement of Flow Magnitude>

From each of the double-faced adhesive films 5 and 8 to 11, a specimen having a size of 2 mm×10 mm was accurately cut out. As shown in the plan view of FIG. 3, each of the specimens (double-faced adhesive films) was sandwiched between a 42-alloy lead frame 3 and a 4 mm×4 mm glass chip 5, and the glass chip 5 was pressure bonded at 140° C. with 50 N for 90 seconds.

The width (a) of the double-faced adhesive film before pressure bonding and the maximum width (b) of the double-faced adhesive film after pressure bonding (FIG. 4) were measured in micron units by using a metallurgical microscope and an image analyzer manufactured by Olympus Corp., and the flow magnitude was obtained on the basis of the following formula. The respective flow magnitudes are shown in Table 4.

Flow magnitude=(Maximum width (b) of the double-faced adhesive film after pressure bonding)−(width (a) of the double-faced adhesive film before pressure bonding) Formula

<Evaluation of Peel Strength of Double-Faced Adhesive Film>

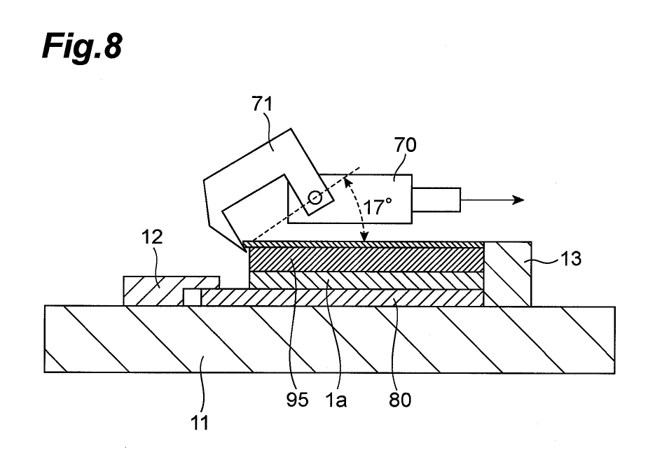

FIG. 8 is a schematic view illustrating a measurement method of peel strength.

By measuring the chip peel strength by use of a measurement device shown in FIG. 8, which was an improved push pull gauge, a peel adhesive force at a high temperature was measured. The results of the measurement are shown in Table 4.

A 400-mm thick wafer was half cut to a 250-μm thickness, and by breaking the wafer by applying force toward the backside thereof, a 5 mm×5 mm silicon chip 95 having a 150-μm thick protrusion in the edge portion thereof was prepared. Then, the double-faced adhesive film was cut to a size of 5 mm×5 mm, and the thus cut double-faced adhesive film was sandwiched between the silicon chip 95 and the 42-alloy lead frame 80. The double-faced adhesive film was pressure bonded at 150° C. for 5 seconds while applying a load of 500 g, then the double-faced adhesive film was further post-cured by heating at 180° C. for 60 minutes, and thus obtained was a laminate in which the silicon chip 95 was bonded to the 42-alloy lead frame through the intermediary of an adhesive layer 1a being a cured body of the double-faced adhesive film.

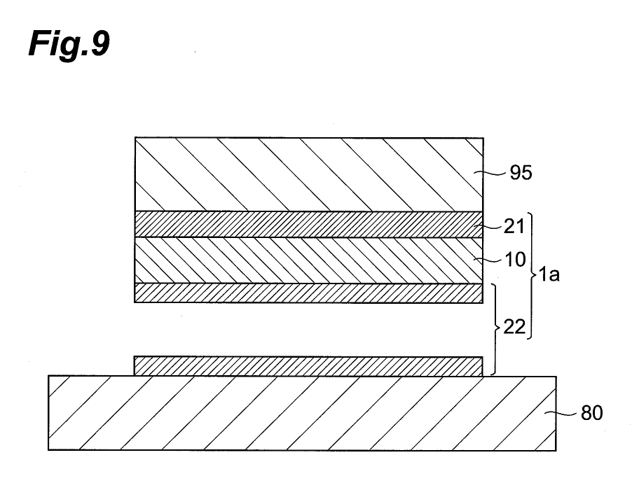

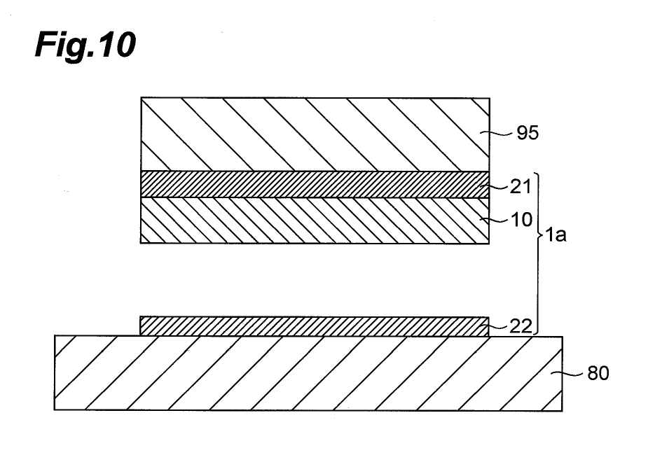

The obtained laminate was fixed on a hot plate 11 with a 42-alloy lead frame fixture 12 and a sample fixing member 13, and was heated at 260° C. for 20 seconds. Successively, a chip peeling jig 71, fitted to a push pull gauge 70, was hooked to the protrusion of the silicon chip 95, and under this condition, the push pull gauge was pulled toward the direction of the arrow in the figure, and by detecting the weight at that time with a push pull gauge 70, the peel strength of the chip peeling was obtained. In general, the higher this numerical value is, the more unlikely the breakage of the adhesive layer at high temperatures occurs. By observing the fracture surface after peeling, it was determined whether the fracture mode is the cohesive failure (A) of the adhesive layer 22 as in FIG. 9 or the failure (B) of the adhesive layer/supporting film 10 interface as in FIG. 10. Further, by using the specimens immersed in NMP or methanol, the peel strengths were measured in the same manner as described above. The measurement results are collectively shown in Table 4.

TABLE 4

| Double-faced adhesive film | | | 5 | 8 | 9 | 10 | 11 |
|---|---|---|---|---|---|---|---|
| Adhesive layer formation method | | | Application | | | Lamination | |
| Flow magnitude (μm) | | | 1500 | 800 | >4000 | 1400 | 600 |
| Peel strength | After heating | | 12 | 10 | 15 | 7 | 6 |
| (N/chip, 5 mm) | (Fracture mode) | | (A) | (A) | (A) | (B) | (B) |
| | After solvent | NMP | 1 | 1 | 1 | 0.3 | 0.3 |
| | immersion | Methanol | 4 | 3 | 2 | 0.2 | 0.2 |

As shown in Table 4, according to the double-faced adhesive films 5, 8 and 9 each formed by a method including application, high peel strength was maintained both after heating and after solvent immersion. In particular, in each of the double-faced adhesive films 5 and 8 in which the flow magnitude was 0 to 2000 μm, a sufficiently high peel strength was maintained even after methanol immersion.

<Preparation of Double-Faced Adhesive Films>

(Double-Faced Adhesive Film 12)

On both sides of the double-faced adhesive film 1, a polyethylene terephthalate film (trade name: GE-50, manufactured by Teijin DuPont Films Ltd.) was laminated at 140° C./0.2 MPa and 1.0 m/min. Thus, a five-layer-structured double-faced adhesive film 12 in which the polyethylene terephthalate film was laminated as cover film on both sides of the double-faced adhesive film 1 was obtained.

(Double-Faced Adhesive Film 13)

In the same manner as described above, a five-layer-structured double-faced adhesive film 13 in which the polyethylene terephthalate film was laminated as cover film on both sides of the double-faced adhesive film 5 was obtained.

(Double-Faced Adhesive Film 14)

In the same manner as described above, a five-layer-structured double-faced adhesive film 14 in which the polyethylene terephthalate film was laminated as cover film on both sides of the double-faced adhesive film 9 was obtained.

(Double-Faced Adhesive Film 15)

In the same manner as described above, a five-layer-structured double-faced adhesive film 15 in which the polyethylene terephthalate film was laminated as cover film on both sides of the double-faced adhesive film 3 was obtained.

(Double-Faced Adhesive Film 16)

A five-layer-structured double-faced adhesive film 16 was obtained through the same steps as for the double-faced adhesive film 12 except that a 50-μm thick polyethylene film (trade name: NF-15, manufactured by Tamapoly Co., Ltd., coefficient of linear expansion: 160 ppm) was used as a “supporting film 4” in place of the supporting film 1.

(Double-Faced Adhesive Film 17)

In the same manner as described above, a five-layer-structured double-faced adhesive film 17 in which the polyethylene terephthalate film was laminated as cover film on both sides of the double-faced adhesive film 7 was obtained.

(Double-Faced Adhesive Film 18)

A five-layer-structured double-faced adhesive film 18 was obtained through the same steps as for the double-faced adhesive film 12 except that the first adhesive layer and the second adhesive layer were formed by using the varnish 4.

(Double-Faced Adhesive Film 19)

The varnish 1 was applied to a polyethylene terephthalate film having undergone a release treatment, and heated at 80° C. for 30 minutes and successively at 150° C. for 30 minutes, subsequently the polyethylene terephthalate film was peeled off at room temperature (25° C.), and thus a 100-μm thick adhesive layer was formed. Further, on both sides of the adhesive layer, a polyethylene terephthalate film (trade name: GE-50, manufactured by Teijin DuPont Films Ltd.) was laminated at 140° C./0.2 MPa and 1.0 m/min. Thus, a three-layer-structured double-faced adhesive film 19 in which a polyethylene terephthalate film was laminated as cover film on both sides of a single-layered adhesive layer was obtained.

<Coefficient of Linear Expansion of Supporting Film>

From the supporting film 4, a 4×20 mm sized sample was cut out. For the sample, the displacement magnitude of the sample was measured, by using the TMA 120 manufactured by Seico Electronics Industrial Co., Ltd., under the following conditions: Extension; the temperature increase rate: 5° C./min; and the length of the measurement sample: 10 mm, and thus the coefficient of linear expansion was obtained. Consequently, the coefficient of linear expansion of the supporting film 4 was 160 ppm.

<Evaluation of Double-Faced Adhesive Films>

(Exterior Foreign Matter)

From each of the double-faced adhesive films, a 100 mm×100 mm sample was cut out, and at ten positions in each of the samples, 0.5 to 10 mm diameter holes were drilled by using a punch or a cutter knife.

Subsequently, when the cover films were arranged, the cover films were peeled off, and then the exterior appearance of each of the double-faced adhesive films was observed by using a metallurgical microscope and an image analyzer manufactured by Olympus Corp., and thus the occurrence or nonoccurrence of foreign matter such as whiskers and burrs of 500 μm or larger on the films or processing points was identified.

(Thermal Shrinkage Factor)

When the cover films were arranged, the cover films were peeled off, and then from each of the double-faced adhesive films, a 80 mm×80 mm sized specimen was cut out. A mark point was put at the center of each side of the cut-out specimens, and the lengths between the opposite mark points were measured to the unit of 0.001 mm.

Next, the specimens were heated for 1 hour in a furnace maintained at 180° C. under a condition allowing free shrinkage. The lengths between the same mark points of the specimens after heating as the points of the specimens before heating were measured to the unit of 0.001 mm. The ratios of the differences, between before and after heating, of the lengths between the mark points to the lengths between the mark points before heating were taken as the thermal shrinkage factors (%).

(Chip Warpage)

When the cover films were arranged, the cover films were peeled off, and then from each of the double-faced adhesive films, a 12 mm×12 mm specimen was accurately cut out. Each of the cut-out specimens was placed on a 42A lead frame.

Next, a 100-μm silicon wafer was cut out to a size of 10×10 mm. The silicon chip was heat-pressure bonded to the lead frame by using the heat-pressure bonding tester (manufactured by Nikka Setsubi Engineering Co., Ltd.) under the conditions described below. The silicon chip warpage which occurred at the time of heat-pressure bonding was measured by using a non-contact roughness gauge (manufactured by Keyence Corp.).

Temperature of a hot plate: The glass transition temperature, after curing, of the second adhesive layer +80° C. (for example, in the case of the double-faced adhesive film in which the second adhesive layer was formed with the varnish 2, the temperature of the hot plate was set at 112° C. (=52° C.+60° C.).)
Pressure bonding conditions: 10 N×10 sec

In Table 5 and Table 6, the structure and the evaluation results of the double-faced adhesive films are shown.

TABLE 5

| Double-faced adhesive film | 12 | 13 | 14 | 15 | 16 | 17 | 18 |
|---|---|---|---|---|---|---|---|
| Supporting film | 1 | 1 | 1 | 2 | 3 | 4 | 1 |
| Fist adhesive layer | 1 | 1 | 3 | 1 | 1 | 1 | 4 |
| Second adhesive layer | 2 | 1 | 3 | 2 | 2 | 2 | 4 |
| Cover film | Present | Present | Present | Present | Present | Present | Present |
| Exterior foreign matter | Absent | Absent | Absent | Absent | Absent | Absent | Absent |
| Thermal shrinkage factor (%) | <0.3 | <0.3 | <0.3 | <0.3 | 2.3 | 1.5 | <0.3 |
| Chip warpage (μm) | 65 | 80 | 60 | 60 | 70 | 70 | 250 |

TABLE 6

| | | | | | |
|---|---|---|---|---|---|
| Double-faced | 1 | 5 | 9 | 3 | 19 |
| adhesive film | | | | | |
| Supporting film | 1 | 1 | 1 | 2 | Absent |
| Fist adhesive layer | 1 | 1 | 3 | 1 | 1 |
| Second adhesive layer | 2 | 1 | 3 | 2 | Absent |
| Cover film | Absent | Absent | Absent | Absent | Present |
| Exterior foreign matter | Present | Present | Present | Present | Absent |
| Thermal shrinkage | <0.3 | <0.3 | <0.3 | <0.3 | 1.5 |
| factor (%) | | | | | |
| Chip warpage (μm) | 65 | 80 | 60 | 60 | 80 |

As shown in Table 5 and Table 6, in the double-faced adhesive films 12 to 18, the presence of the foreign matter due to the hole drilling processing was not identified, and it was identified that the foreign matter was removed together with the cover films. Additionally, the double-faced adhesive films 12 to 18 were such that low thermal shrinkage factors were attained and the suppression of the deformation accompanying heating was made possible. In particular, the double-faced adhesive films 12 to 15 and 18 each using a supporting film having a coefficient of linear expansion of 100 ppm or less each attained a low thermal shrinkage factor of less than 0.3. Additionally, the double-faced adhesive films 12 to 17 in each of which the Tgs, after curing, of the adhesive layers were lower than 100° C. displayed excellent properties also with respect to the chip warpage suppression.

On the other hand, in the double-faced adhesive films 1, 5, 9 and 3 which used no cover films, the presence of the foreign matter accompanying the hole drilling processing was found. Additionally, the double-faced adhesive film 19 which used no supporting film was such that the thermal shrinkage factor was large and the deformation due to heating occurred readily.

### INDUSTRIAL APPLICABILITY

The double-faced adhesive films according to the present invention can be suitably used for adhering one or both of a semiconductor element such as IC, LSI, LED or discrete semiconductor and a MEMS element to a substrate such as a lead frame, a ceramic substrate, a glass epoxy substrate, a BT substrate, a polyimide substrate or a liquid crystal substrate.

### REFERENCE SIGNS LIST

1a . . . Adhesive layer, 2 . . . Electronic component module, 3 . . . Lens, 5 . . . LED printer head, 7 . . . Photosensitive drum, 10 . . . Supporting film, 11 . . . Hot plate, 12 . . . 42-Alloy lead frame fixture, 13 . . . Sample fixing member, 21 . . . First adhesive layer, 22 . . . Second adhesive layer, 31, 32 . . . Cover film, 40 . . . Substrate, 45 . . . Element (LED chip), 50 . . . Light, 60 . . . Predetermined position, 70 . . . Push pull gauge, 71 . . . Chip peeling jig, 80 . . . 42-Alloy lead frame, 90 . . . Glass chip, 95 . . . Silicon chip, 100 . . . Double-faced adhesive film.

1. A double-faced adhesive film comprising:
a supporting film;
a first adhesive layer laminated on one surface of the supporting film; and
a second adhesive layer laminated on the other surface of the supporting film,
wherein glass transition temperatures, after curing, of the first adhesive layer and the second adhesive layer are each 100° C. or lower, and
the first adhesive layer and the second adhesive layer are the layers capable of being formed by a method comprising steps of directly applying a varnish to the supporting film and drying the applied varnish.

2. The double-faced adhesive film according to claim 1, wherein the glass transition temperature, after curing, of the first adhesive layer is higher by 10° C. or more than the glass transition temperature, after curing, of the second adhesive layer.

3. The double-faced adhesive film according to claim 1, wherein flow magnitudes of the first adhesive layer and the second adhesive layer are each 0 to 2000 μm.

4. The double-faced adhesive film according to claim 1, wherein the first adhesive layer and/or the second adhesive layer comprises a thermoplastic resin and a thermosetting resin.

5. The double-faced adhesive film according to claim 4, wherein the first adhesive layer and/or the second adhesive layer further comprises a filler.

6. The double-faced adhesive film according to claim 4, wherein the thermoplastic resin further comprises a polyimide resin.

7. The double-faced adhesive film according to claim 4, wherein a glass transition temperature of the thermoplastic resin is 100° C. or lower.

8. The double-faced adhesive film according to claim 1, wherein the supporting film has a coefficient of linear expansion of 100 ppm or less.

9. The double-faced adhesive film according to claim 1, wherein the supporting film has a glass transition temperature of 100° C. or higher.

10. The double-faced adhesive film according to claim 1, wherein the supporting film is a film of a polymer selected from the group consisting of polyethylene terephthalate, polybutylene terephthalate, polyethylene naphthalate, polyimide, polyamide, polyamideimide, polyacetal, polycarbonate, polyethersulfone, polyphenylene sulfide, polyphenylene ether, polyetherketone, polyarylate, polyetheramide, polyetherimide, polyetheramideimide, wholly aromatic polyester and liquid crystal polymers.

11. The double-faced adhesive film according to claim 10, wherein the supporting film is a film of a polymer selected from the group consisting of polyethylene terephthalate, polybutylene terephthalate, polyethylene naphthalate, polyimide, polyamide, polyamideimide, polyacetal, polycarbonate, polyethersulfone, polyphenylene sulfide, polyphenylene ether, polyetherketone, polyarylate and liquid crystal polymers.

12. The double-faced adhesive film according to claim 11, wherein the supporting film is a film of a polymer selected from the group consisting of aromatic polyimide, aromatic polyamideimide, aromatic polyethersulfone, polyphenylene sulfide, aromatic polyetherketone, polyarylate, polyethylene naphthalate and liquid crystal polymers.

13. An electronic component module comprising:
a substrate;
a plurality of elements mounted on the substrate, the plurality of elements being selected from semiconductor elements and MEMS elements; and
an adhesive layer intervening between the substrate and the elements,
wherein the adhesive layer is formed of the double-faced adhesive film according to claim 1.

14. The double-faced adhesive film according to claim 1, comprising:
cover films laminated respectively on the surfaces, opposite to the supporting film, of the first adhesive layer and the second adhesive layer,
wherein the double-faced adhesive film is used for the purpose of adhering a semiconductor element and/or a MEMS element to the substrate.

15. The double-faced adhesive film according to claim 14, being used for the purpose of adhering a semiconductor element and/or a MEMS element to a substrate by a method comprising a step of hole drilling processing of the double-faced adhesive film and a step of removing the cover films from the double-faced adhesive film having been subjected to hole drilling processing.

16. The double-faced adhesive film according to claim 15, wherein from the double-faced adhesive film having been subjected to the hole drilling processing, the cover films are removed together with foreign matter produced by the hole drilling processing.

17. An electronic component module comprising:
a substrate;
a plurality of elements mounted on the substrate, the plurality of elements being selected from semiconductor elements and MEMS elements; and
an adhesive layer intervening between the substrate and the elements,
wherein the adhesive layer is formed of the double-faced adhesive film according to claim 14 having been subjected to removal of the cover films.

18. A double-faced adhesive film comprising:
a supporting film;
a first adhesive layer laminated on one surface of the supporting film; and
a second adhesive layer laminated on the other surface of the supporting film,
wherein glass transition temperatures, after curing, of the first adhesive layer and the second adhesive layer are each 100° C. or lower, and
the glass transition temperature, after curing, of the first adhesive layer is higher by 10° C. or more than the glass transition temperature, after curing, of the second adhesive layer; and
the supporting film has a coefficient of linear expansion of 100 ppm or less.

19. The double-faced adhesive film according to claim 18, wherein the first adhesive layer comprises a thermoplastic resin, a thermosetting resin and a filler.

20. The double-faced adhesive film according to claim 18, wherein the second adhesive layer comprises a thermoplastic resin, a thermosetting resin and a filler.

21. The double-faced adhesive film according to claim 18, wherein the supporting film is a film of a polymer selected from the group consisting of polyethylene terephthalate, polybutylene terephthalate, polyethylene naphthalate, polyimide, polyamide, polyamideimide, polyacetal, polycarbonate, polyethersulfone, polyphenylene sulfide, polyphenylene ether, polyetherketone, polyarylate, polyetheramide, polyetherimide, polyetheramideimide, wholly aromatic polyester and liquid crystal polymers.

22. An electronic component module comprising:
a substrate;
a plurality of elements mounted on the substrate, the plurality of elements being selected from semiconductor elements and MEMS elements; and
an adhesive layer intervening between the substrate and the elements,
wherein the adhesive layer is formed of the double-faced adhesive film according to claim 18.

23. A double-faced adhesive film comprising:
a supporting film; and
adhesive layers laminated respectively on both surfaces of the supporting film,
wherein the adhesive layers are the layers capable of being formed by a method comprising steps of directly applying a varnish to the supporting film and drying the applied varnish, and
flow magnitudes of the adhesive layers are each 0 to 2000 μm and the adhesive layers after curing each have a glass transition temperature of 100° C. or lower.

24. The double-faced adhesive film according to claim 23, wherein the supporting film has a glass transition temperature of 100° C. or higher and a coefficient of linear expansion of 100 ppm or less.

25. The double-faced adhesive film according to claim 23, wherein the supporting film is a film of a polymer selected from the group consisting of polyethylene terephthalate, polybutylene terephthalate, polyethylene naphthalate, polyimide, polyamide, polyamideimide, polyacetal, polycarbonate, polyethersulfone, polyphenylene sulfide, polyphenylene ether, polyetherketone, polyarylate, polyetheramide, polyetherimide, polyetheramideimide, wholly aromatic polyester and liquid crystal polymers.

26. The double-faced adhesive film according to claim 23, wherein the adhesive layers each comprise a polyimide resin and a thermosetting resin.

27. An electronic component module comprising:
a substrate;
elements mounted on the substrate, the elements being selected from semiconductor elements and MEMS elements; and
an adhesive layer intervening between the substrate and the elements,
wherein the adhesive layer is formed of the double-faced adhesive film according to claim 23.

28. A double-faced adhesive film comprising:
a supporting film;
adhesive layers laminated respectively on both surfaces of the supporting film, and
cover films laminated respectively on the surfaces, opposite to the supporting film, of the adhesive layers,
wherein the double-faced adhesive film is used for the purpose of adhering a semiconductor element and/or a MEMS element to the substrate.

29. The double-faced adhesive film according to claim 28, being used for the purpose of adhering a semiconductor element and/or an MEMS element to a substrate by a method comprising a step of hole drilling processing of the double-faced adhesive film and a step of removing the cover films from the double-faced adhesive film having been subjected to hole drilling processing.

30. The double-faced adhesive film according to claim 29, wherein from the double-faced adhesive film having been subjected to the hole drilling processing, the cover films are removed together with foreign matter produced by the hole drilling processing.

31. The double-faced adhesive film according to claim 28, wherein the supporting film has a coefficient of linear expansion of 100 ppm or less and the adhesive layers after curing each have a glass transition temperature of lower than 100° C.

32. The double-faced adhesive film according to claim 28, wherein the supporting film is a film of a polymer selected from the group consisting of polyethylene terephthalate, polybutylene terephthalate, polyethylene naphthalate, polyimide, polyamide, polyamideimide, polyacetal, polycarbonate, polyethersulfone, polyphenylene sulfide, polyphenylene ether, polyetherketone, polyarylate, polyetheramide, polyetherimide, polyetheramideimide, wholly aromatic polyester and liquid crystal polymers.

33. The double-faced adhesive film according to claim 28, wherein the respective adhesive layers have the same compositions as each other.

34. The double-faced adhesive film according to claim 28, wherein the respective adhesive layers each comprise a thermoplastic resin having a glass transition temperature of 100° C. or lower, a thermosetting resin and a filler.

35. An electronic component module comprising:
a substrate;
a plurality of elements mounted on the substrate, the plurality of elements being selected from semiconductor elements and MEMS elements; and
an adhesive layer intervening between the substrate and the elements,
wherein the adhesive layer is formed of the double-faced adhesive film according to claim 28 having been subjected to removal of the cover films.
